(19) United States
(12) Patent Application Publication
(10) Pub. No.: US 2018/0302093 A1
(43) Pub. Date: Oct. 18, 2018

(54) DYNAMIC IMPEDANCE CONTROL FOR VOLTAGE MODE DRIVERS

(71) Applicant: SanDisk Technologies LLC, Plano, TX (US)

(72) Inventors: Shiv Harit Mathur, Bangalore (IN); Anand Sharma, Bangalore (IN); Ramakrishnan Karungulam Subramanian, Bangalore (IN); Nitin Gupta, Noida (IN)

(73) Assignee: SanDisk Technologies LLC, Plano, TX (US)

(21) Appl. No.: 15/626,580

(22) Filed: Jun. 19, 2017

(30) Foreign Application Priority Data
Apr. 12, 2017 (IN) 201741013097

(51) Int. Cl. H03K 19/0185; H03K 19/21

(52) U.S. Cl. CPC H03K 19/018557; H03K 19/215

(57) ABSTRACT

A circuit may receive control signals to generate an output signal with pulses corresponding to pulses of a source signal. The circuit may include a primary circuit and an auxiliary circuit. The primary circuit may constantly participate in the generation of pulses of the output signal. The auxiliary circuit may selectively participate with the primary circuit in the generation of the pulses. For two consecutive pulses of the output signal, whether the auxiliary circuit participates in generating the latter of the two pulses may depend on whether a threshold level is crossed during generation of the consecutive pulses.

### CROSS-REFERENCE TO RELATED APPLICATIONS

This application claims priority to Indian Patent Application No. 201741013097, filed Apr. 12, 2017. The contents of Indian Patent Application No. 201741013097 are incorporated by reference in their entirety.

### BACKGROUND

In storage devices, the speed at which a controller can communicate with memory dies is largely dependent on the bandwidth of the channel between the controller and the memory dies, which in turn is dependent upon characteristics of the channel and the capacity of the dies. In order to achieve higher speeds, the loads of the dies may be reduced. However, at some point, reduction in the memory die load may be undesirable, especially as the number of memory dies in the storage device increases. Additionally, increasing the speed across the channel may create or exacerbate various undesirable effects, such as self-noise and cross-talk between parallel lines of the channel, which in turn creates reflections and degradation in signal integrity.

In order to improve signal integrity, some storage devices perform impedance calibration in order to reduce driver variation that results from varying process, voltage, and temperature (PVT) conditions. In addition, some storage devices utilize on-die termination (ODT) to reduce impedance mismatch. Although such features may reduce the problems created by communicating at higher speeds, they do not eliminate them, especially where new design specifications call for still higher speeds and larger numbers of dies. Thus, other ways to further improve signal integrity may be desirable.

### BRIEF DESCRIPTION OF THE DRAWINGS

The accompanying drawings, which are incorporated in and constitute a part of this specification illustrate various aspects of the invention and together with the description, serve to explain its principles. Wherever convenient, the same reference numbers will be used throughout the drawings to refer to the same or like elements.

FIG. 1 is a block diagram of an example circuit system configured to output an output signal.

FIG. 2A is a timing diagram of an example source signal generated by a source circuit of the circuit system of FIG. 1 with pulses above or below an associated threshold level.

FIG. 2B is a timing diagram of an example output signal generated by the circuit system of FIG. 1 with pulses above or below an associated threshold level.

FIG. 3 is a partial circuit schematic diagram, showing an example circuit configuration of an output driver circuit of the circuit system of FIG. 1.

FIG. 4 is a circuit schematic of an example circuit configuration of the output driver circuit.

FIG. 5 is a block diagram of an example configuration of a driver control circuit of the circuit system of FIG. 1.

FIG. 6A is a timing diagram of signals communicated by the circuit components of the circuit system to control a primary circuit of the output driver circuit.

FIG. 6B is a timing diagram of signals communicated by the circuit components of the circuit system to control an auxiliary circuit of the output driver circuit.

FIG. 7 is a block diagram of an example configuration of a dynamic impedance control circuit shown in FIG. 5.

FIG. 8 is a timing diagram of signals communicated by the circuit components of the dynamic impedance control circuit shown in FIG. 7.

FIG. 9 is a block diagram of another example circuit system configured to generate an output signal.

FIG. 10 is a flow chart of an example method of generating an output signal.

FIG. 11 is a flow chart of an example method of generating a control signal used to cause an auxiliary circuit to selectively participate in generating an output signal.

### DETAILED DESCRIPTION

Overview

The following embodiments describe a variable impedance output circuit configured to generate pulses of an output signal with varying impedances according to the voltage levels of the pulses. In one embodiment, a circuit includes a first output circuit and a second output circuit. The first output circuit is configured to generate an output signal. The second output circuit is configured to contribute to the generation of the output signal based on whether the first output circuit generates a voltage that crosses a threshold level during generation of consecutive pulses of the output signal.

In some embodiments, the second output circuit is configured to contribute to generation of a pulse of the output signal in response to the first output circuit generating a voltage that crosses the threshold level during generation of the pulse and an immediately preceding pulse.

In some embodiments, the second output circuit is configured to not contribute to the generation of a pulse in response to the first output circuit generating a voltage that does not cross the threshold level during generation of the pulse and the immediately preceding pulse.

In some embodiments, the circuit further includes: a control circuit configured to: output a control signal to cause the second output circuit to participate in generation of a pulse of the output signal in response to the threshold level being crossed during the generation of the pulse and an immediately preceding pulse of the output signal, and output the control signal to cause the second output circuit to not participate in the generation of the pulse in response to the threshold level not being crossed during generation of the pulse and the immediately preceding pulse.

In some embodiments, the control circuit is further configured to receive an input signal, and perform an XOR operation on pulses of the input signal corresponding to the pulse and the immediately preceding pulse of the output signal in order to generate the control signal.

In some embodiments, the control circuit is further configured to receive a clock signal oscillating at a rate that is twice a rate of the output signal, and perform the XOR operation according to transitions of the clock signal.

In some embodiments, the control circuit further comprises a first tracking circuit and a second tracking circuit. The first tracking circuit is configured to track the input signal on one of rising edges or falling edges of the clock signal to generate a first tracked signal, and output the first tracked signal to a first input of an XOR logic circuit for performance of the XOR operation. The second tracking circuit is configured to track the first tracked signal on the other of the rising edges or the falling edges of the clock signal to generate a second tracked signal, and output the second tracked signal to a second input of the XOR logic circuit for performance of the XOR operation.

In some embodiments, the circuit further includes: a control circuit configured to: receive an input signal corresponding to the output signal; generate a control signal based on the input signal, where a voltage level of the control signal indicates a voltage level at which the first output circuit is to generate a next pulse of the consecutive pulses; and compare the voltage level of a control signal with a voltage level of a current pulse of the consecutive pulses of the output signal. The second output circuit is configured to contribute to generation of the next pulse in response to the comparison indicating that the first output circuit is to generate a voltage that crosses the threshold level during generation of the current pulse and the immediately preceding pulse.

In another embodiment, a circuit includes an output driver circuit and a driver control circuit. The output driver circuit is configured to generate an output signal with a variable impedance. The driver control circuit is configured to output a control signal to configure the output driver circuit to generate a current pulse of the output signal with the variable impedance at a first impedance value in response to the current pulse having a different logic level than an immediately preceding pulse of the output signal. In addition, the output driver circuit is configured to output the control signal to configure the output driver circuit to generate the current pulse with the variable impedance at a second impedance value in response to the current pulse having the same logic level as the immediately prior pulse.

In some embodiments, the first impedance value is lower than the second impedance value.

In some embodiments, the output driver circuit includes a first push-pull circuit configured to generate the output signal, and a second push-pull circuit configured to generate the output signal. The driver control circuit is configured to output the control signal to activate both the first push-pull circuit and the second push-pull circuit to configure the output driver circuit to generate the output signal with the variable impedance at the first impedance value. In addition, the driver control circuit is configured to output the control signal to activate the first push-pull circuit and deactivate the second push-pull circuit to configure the output driver circuit to generate the output signal with the variable impedance at the second impedance value.

In some embodiments, the driver control circuit is configured to perform an XOR operation on pulses of an input signal corresponding to the pulse and the immediately preceding pulse of the output signal in order to generate the control signal.

In some embodiments, the control circuit is further configured to receive a clock signal oscillating at a rate that is twice a rate of the output signal, and perform the XOR operation once per clock cycle of the clock signal.

In another embodiment, a circuit includes an input circuit and a comparison circuit. The input circuit is configured to receive a signal comprising a plurality of pulses. The comparison circuit is configured to compare logic levels of consecutive pulses of the plurality of pulses, output a control signal to activate a secondary circuit of an output driver circuit in response to the comparison indicating that the logic levels are different, and output the control signal to deactivate the secondary circuit in response to the comparison indicating that the logic levels are the same.

In some embodiments, the comparison circuit includes and XOR logic circuit and a tracking circuit. The XOR logic circuit is configured to perform an XOR operation on the logic levels and generate an XOR output signal based on the XOR operation. The tracking circuit is configured to track the XOR output signal on edges of a clock signal in order to generate the control signal.

In some embodiments, the input circuit includes a first tracking circuit and a second tracking circuit. The first tracking circuit is configured to track the signal on one of rising edges or falling edges of the clock signal to generate a first tracked signal. In addition, the second tracking circuit is configured to track the first tracked signal on the other of the rising edges or the falling edges of the clock signal. The XOR logic circuit is further configured to receive the first tracked signal and the second tracked signal, and perform the XOR operation using the first tracked signal and the second tracked signal.

In some embodiments, the first tracking circuit is configured to track the signal on the falling edges, the second tracking circuit is configured to track the first tracked signal on the rising edges, and the tracking circuit of the comparison circuit is configured to track the XOR output signal on the rising edges.

In some embodiments, the input circuit is further configured to receive a clock signal, where a rate of the clock signal is twice a rate of the signal.

In some embodiments, the input circuit further includes a logic circuit configured between the first tracking circuit and the second tracking circuit. The logic circuit is configured to pass the first tracked signal to the second tracking circuit in response to an enable signal indicating that the output driver circuit is to generate an output signal based on the signal.

In some embodiments, an output circuit is configured to output an intermediate signal to a multiplexer circuit. The second tracking circuit of the input circuit is configured to output to the second tracked signal to both the output circuit for generation of the intermediate signal and to the XOR logic circuit for generation of the control signal.

Other embodiments are possible, and each of the embodiments can be used alone or together in combination. Accordingly, various embodiments will now be described with reference to the attached drawings.

### Embodiments

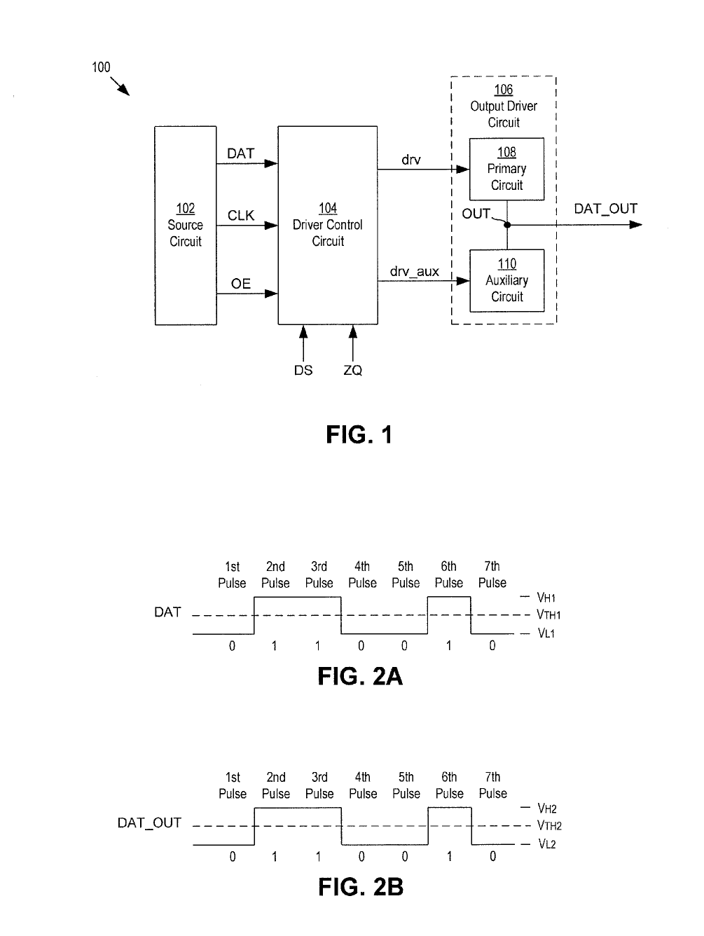

FIG. 1 shows a block diagram of an example circuit system 100 that may be configured to generate an output signal DAT_OUT. As shown in FIG. 1, the circuit system 100 may include a source circuit 102, a driver control circuit 104, and an output driver circuit 106.

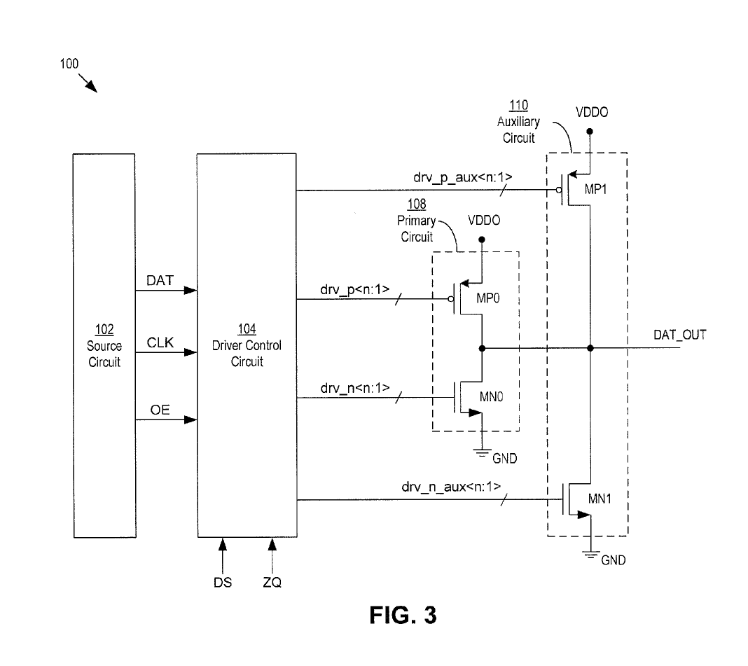

The source circuit 102 may be configured to generate and output a source signal DAT. FIG. 2A shows a timing diagram of an example pulse sequence or at least a portion of a pulse sequence of the source signal DAT that the source circuit 102 may output. As shown in FIG. 2, a peak amplitude of each pulse may be generated at an associated first (e.g., high) voltage level V_{H1} or at an associated second (e.g., low) voltage level V_{L1}. As used herein, and unless specified otherwise, a pulse described as being at a certain voltage level, generated at a certain voltage level, and/or output at a certain voltage level, may refer to a peak amplitude of the pulse being at, generated at, and/or output at the certain voltage level. The high voltage level V_{H1} and the low voltage level V_{L1} associated with the source signal DAT may each be representative of a single voltage level, a set or range of voltage levels, maximum high and low voltage levels of respective ranges, average high and low voltage levels, and/or the high voltage level V_{H1} may be a voltage level that is higher than an associated threshold level V_{TH1} and the low voltage level V_{L1} may be a level that is lower than the associated threshold level V_{TH1}. For some example configurations, the value of the associated threshold level V_{TH1} may be a middle of halfway value between the high voltage level V_{H1} and the low voltage level V_{L1} (i.e., (V_{H1}+V_{L1})/2)), although other values for the associated threshold level V_{TH1} may be possible.

In addition, for two consecutive pulses of the source signal DAT, where the two pulses are at different voltage levels (i.e., one of the pulses is at the high voltage level V_{H1} and the other pulse is at the low voltage level V_{L1}), then the voltage of the source signal DAT may cross the associated threshold level V_{TH1} over the two pulses. In particular, the voltage of the source signal DAT may cross the associated threshold V_{TH1} as the pulse sequence transitions from the first pulse of the second pulse. On the other hand, where the two pulses are at the same voltage level (e.g., both are at the high voltage level V_{H1} or both are at the low voltage level V_{L1}), then the voltage of the source signal DAT may not cross the associated threshold level V_{TH1} over the two pulses as the pulse train transitions from the first pulse to the second pulse.

In some example configurations, the source signal DAT may be a data signal carrying data. The data signal may include a sequence of pulses corresponding to a bit sequence of the data, with each pulse corresponding to a bit (e.g., a single bit) of the bit sequence. Accordingly, each pulse may be at a voltage level that corresponds to a logic level or logic value (e.g., a binary logic level or a binary logic value) of “1” or “0” to indicate the bit value of the bit to which the pulse corresponds. In a particular example configuration, each pulse of the pulse sequence generated at the high voltage level V_{H1} indicates that its corresponding bit has a logic 1 level and each pulse of the pulse sequence generated at the low voltage level V_{L1} indicates that its corresponding bit has a logic 0 level. This example configuration is shown in FIG. 2A, where “1” and “0” labels are positioned below each pulse to indicate the logic level to which each pulse corresponds. Accordingly, a pulse that is higher or detected as being higher than the associated threshold level V_{TH1} may be identified as corresponding to a logic 1 level, and a pulse that is lower or detected as being lower than the associated threshold level V_{TH1} may be identified as corresponding to a logic 0 level. For two consecutive pulses of the data signal DAT, if the two consecutive pulses correspond to different logic levels, a transition of the voltage from the associated high level V_{H1} to the associated low level V_{L1} (or from the associated low level V_{L1} to the associated high level V_{H1}) that crosses the associated threshold level V_{TH1} may occur. The transition may occur as the pulse train transitions from the first pulse to the second pulse. Conversely, if the two consecutive pulses correspond to the same logic level, then as the pulse train transitions from the first pulse to the second pulse, the voltage of the source signal DAT may not cross the associated threshold level V_{TH1}.

Referring back to FIG. 1, the widths of the pulses, period length of the pulses, and/or rate at which the pulses occur may depend on a clock rate or frequency of a clock signal CLK, which may be also output by the source circuit 102. In some example configurations, the clock rate may be twice the rate of the source signal DAT, as described in further detail below, although other timing relationships between the clock rate and the signal rate may be possible. Also, as shown in FIG. 1, the source circuit 102 may output an enable signal (OE), which may indicate whether or not the source circuit 102 has a source signal DAT to be output external to the circuit system 100. For example, the source circuit 102 may output the enable signal OE at an associated enable (e.g., high) level to indicate that the source circuit 102 has a source signal DAT to be output, and at an associated disable (e.g., low) level to indicate that the source circuit 102 does not have a source signal DAT to be output. The enable signal OE being output at the enable level may enable or activate the driver control circuit 104 and the output driver circuit 106 to generate the output signal DAT_OUT with pulses at voltage levels corresponding to the voltage levels and/or logic levels of the pulses of the source signal DAT.

The driver control circuit 104 may be configured to receive the source signal DAT, the clock signal CLK, and the enable signal OE. Based on the levels of these signals, the driver control circuit 104 may be configured to generate driver control signals drv and drv_aux to control the output driver circuit 106 and the voltage levels at which the output driver circuit 106 generates the pulses of the output signal DAT_OUT.

Like the source signal DAT, the output signal DAT_OUT may include a sequence of pulses. FIG. 2B shows a timing diagram of an example pulse sequence or at least a portion of a pulse sequence of the output signal DAT that the output driver circuit 106 may be configured to generate and output. As shown in FIG. 2B, each of the pulses may be generated at an associated high voltage level V_{H2} or at an associated low voltage level V_{L2}. Like the high and low voltage levels V_{H1}, H_{L1} associated with the source signal DAT, the high voltage level V_{H2} and the low voltage level V_{L2} may each be representative of a single voltage level, a set or range of voltage levels, maximum high and low voltage levels of respective ranges, average high and low voltage levels, and/or the high voltage level V_{H2} may be a level that is higher than an associated threshold level V_{TH2} and the low voltage level V_{L2} may be a level that is lower than the associated threshold level V_{T2}. For some example configurations, the value of the associated threshold level V_{TH2} may be a middle of halfway value between the high voltage level V_{H2} and the low voltage level V_{L2}, although other values for the associated threshold level V_{TH2} may be possible.

In addition, like the source signal DAT, for two consecutive pulses of the output signal DAT_OUT, where the two pulses are at different voltage levels (i.e., one of the pulses is at the high voltage level V_{H2} and the other pulse is at the low voltage level V_{L2}) then the voltage of the output signal DAT_OUT generated by the output driver circuit 106 may cross the associated threshold level V_{TH2} during generation of the two pulses. In particular, the voltage of the output signal DAT_OUT may cross the associated threshold level V_{TH2} when the output driver circuit 106 transitions from generating the first pulse to generating the second pulse. On the other hand, where the two pulses are at the same voltage level (e.g., both are at the high voltage level V_{H2} or both are at the low voltage level V_{L2}), then the voltage of the output signal DAT generated by the output driver circuit 106 may not cross the associated threshold level V_{TH2} during generation of the two pulses.

In addition, like the source signal DAT, for some example configurations, the output signal DAT_OUT may be a data signal carrying data. Each pulse of the output signal DAT_OUT may be at a voltage level that corresponds to a logic 1 level or a logic 0 level to indicate the bit value of the bit to which the pulse corresponds. In a particular example configuration, each pulse of the pulse sequence generated at the high voltage level V_{H2} indicates that its corresponding bit has a logic 1 level and each pulse of the pulse sequence generated at the low voltage level V_{L2} indicates that its corresponding bit has a logic 0 level. This example configuration is shown in FIG. 2B, where “1” and “0” labels are positioned below each pulse to indicate the logic level to which each pulse corresponds. Accordingly, a pulse that is higher or detected as being higher than the associated threshold level V_{TH2} may be identified as corresponding to a logic 1 level, and a pulse that is lower or detected as being lower than the associated threshold level V_{TH2} may be identified as corresponding to a logic 0 level. For two consecutive pulses of the output data signal DAT_OUT, if the two consecutive pulses correspond to different logic levels, the output driver circuit 106 may generate the voltage of the output signal DAT_OUT such that a transition of the voltage from the associated high voltage level V_{H2} to the associated low voltage level V_{L2} (or from the low voltage level V_{L2} to the high voltage level V_{H2}) may cross the associated threshold level V_{TH2}. The transition may occur as the pulse train transitions from the first pulse to the second pulse. Conversely, if the two consecutive pulses correspond to the same logic level, then the output driver circuit 106 may generate the voltage of the source signal DAT such that it does not cross the threshold level V_{TH} during generation of the two pulses.

In addition, the high voltage level V_{H1} associated with the source signal DAT and the high voltage level V_{H2} associated with the output signal DAT_OUT may be the same as or different from each other, the low voltage level V_{L1} associated with the source signal DAT and the low voltage level V_{L2} associated with the output signal DAT_OUT may be the same as or different from each other, the threshold level V_{TH1} associated with the source signal DAT and the threshold level V_{TH2} associated with the output signal DAT_OUT may be the same or different from each other, or any combination thereof.

Also, the voltage levels at which the output driver circuit 106 generates each of the pulses of the output signal DAT_OUT may correspond to and/or have a relationship with the voltage levels of the corresponding pulses of the source signal DAT. In one example configuration, as shown in FIGS. 2A and 2B, there may be a direct relationship between the voltage levels of corresponding pulses. For example, as shown in FIGS. 2A and 2B, the first pulse of the source signal DAT is generated at its associated low voltage level V_{L1}, and the corresponding first pulse of the output signal DAT_OUT is similarly generated at its low voltage level V_{L2}. Likewise, the second pulse of the source signal DAT is generated at its associated high voltage level V_{H1}, and the corresponding second pulse of the output signal DAT_OUT is similarly generated at its high voltage level V_{H2}. Other configurations may utilize an inverse relationship instead of a direct relationship between corresponding pulses of the source signal DAT and the output signal DAT_OUT. That is, where a given pulse of the source signal DAT is generated at its associated low voltage level V_{L1}, the corresponding pulse of the output signal DAT_OUT is generated at its associated high voltage level V_{H2}. Similarly, where a given pulse of the source signal DAT is generated at its associated high voltage level V_{H1}, the corresponding pulse of the output signal DAT_OUT is generated at its associated low voltage level V_{L2}. Various relationships between the voltage levels of the source signal DAT and the output signal DAT_OUT may be possible.

In addition or alternatively, other waveforms for the source signal DAT and the output signal DAT_OUT, or other logic level schemes under which the waveforms of the source signal DAT and the output signal DAT_OUT are generated and output, may be possible. For example, instead of a high voltage level corresponding to a logic 1 level and a low voltage level corresponding to a logic 0 level, the high voltage level may correspond to a logic 0 level and the low voltage level may correspond to a logic 1 level. As another example, the pulses of each of the source signal DAT and the output signal DAT_OUT may be generated at more than two voltage levels (i.e., more than a high voltage level and a low voltage level). For some of these configurations, pulses generated at more than two voltage levels which may indicate and/or correspond to more or other than two logic levels. That is, a voltage level of a single pulse may indicate or correspond to a multi-bit or an n-bit value, where n is two or more. Waveforms with pulses generated at more than two voltage levels may be associated with multiple threshold levels. The voltage of the source signal DAT and/or the output signal DAT_OUT may cross at least one of the associated threshold levels over consecutive pulses if the voltage levels of the consecutive pulses are different. Conversely, the voltage may not cross any associated threshold levels may be crossed over the consecutive pulses if their corresponding multi-bit values are the same. Various other waveforms for the source signal DAT and the output signal DAT_OUT may be possible.

As shown in FIG. 1, the output driver circuit 106 may include a primary circuit 108 and an auxiliary or secondary circuit 110, each coupled to an output node OUT at which the output signal DAT_OUT is generated. In a particular example configuration, the primary circuit 108 may be constantly used to generate the output signal DAT_OUT, and the auxiliary circuit 110 may be selectively, variably, or only sometimes used to generate the output data signal DAT_OUT.

Whether the auxiliary circuit 110 is involved, contributes to, or participates in the generation of the output signal DAT_OUT may depend on the voltage levels and/or logic levels of consecutive pulses of the source signal DAT and/or whether the voltage of the output signal DAT_OUT generated by the primary circuit 108 crosses a threshold level during generation of and/or in order to generate the consecutive pulses. In a particular configuration, for two consecutive pulses of the source signal DAT, including a current pulse and an immediately preceding or prior pulse, the auxiliary circuit 110 may contribute to or participate in the generation of a pulse of the output signal DAT_OUT corresponding to the current pulse of the source signal DAT when the logic level of the current pulse is different than the logic level of the immediately preceding pulse. In addition or alternatively, the auxiliary circuit 110 may contribute to or participate in the generation of a pulse of the output signal DAT_OUT corresponding to the current pulse of the source signal DAT when the primary circuit 108 generates the voltage of the output signal DAT_OUT to cross a threshold level during generation of and/or in order to generate the pulse and an immediately preceding pulse of the output signal DAT_OUT. Conversely, the auxiliary circuit 110 may not contribute to and/or participate in the generation of the pulse of the output signal DAT_OUT corresponding to the current pulse of the source signal DAT when the logic level of the current pulse is the same as or matches the logic level of the immediately preceding pulse. In addition or alternatively, the auxiliary circuit 110 may not contribute to and/or participate in the generation of a pulse of the output signal DAT_OUT corresponding to the current pulse of the source signal DAT when the voltage of the output signal DAT_OUT generated by the primary circuit 108 does not cross a threshold level during generation of and/or in order to generate the pulse and an immediately preceding pulse of the output data signal DAT_OUT.

To illustrate with reference to FIGS. 2A and 2B, suppose the two consecutive pulses of the source signal DAT are the first pulse and the second pulse, with the second pulse being the current pulse and the first pulse being the immediately preceding pulse. As shown in FIG. 2A, the source circuit 102 outputs the first and second pulses at two different voltage levels, corresponding to two different logic levels, with the first pulse output at the associated low voltage level V_{L1} corresponding to the logic 0 level and the second pulse output at the associated high voltage level V_{H1} corresponding to the logic 1 level. Accordingly, the primary circuit 108 will generate the corresponding first pulse of the output signal DAT_OUT at the associated low voltage level V_{L2} and the corresponding second pulse of the output signal DAT_OUT at the associated high voltage level V_{H2}, and in doing so, will generate the voltage of the output signal DAT_OUT to cross the associated threshold level V_{TH2} during generation of the first and second pulses of the output signal DAT_OUT. Because primary circuit 108 is to generate the first and second pulses of the output signal DAT_OUT at different voltage levels, at levels corresponding to different logic levels, and/or because the voltage of the output signal DAT_OUT crosses the associated threshold level V_{TH2} during generation of the first and second pulses, then the auxiliary circuit 110 may be involved, contribute, and/or participate in the generation of the second pulse of the output signal DAT_OUT corresponding to the second pulse of the source signal DAT. To further illustrate, suppose the two consecutive pulses of the source signal DAT are the second pulse and the third pulse, with the third pulse being the current pulse and the second pulse being the immediately preceding pulse. Because primary circuit 108 is to generate the second pulse and the third pulse are at the same, high voltage level V_{H2}, corresponding to the same logic level (i.e., the logic 1 level), and/or because the voltage of the output signal DAT_OUT does not cross the associated threshold level V_{TH2} during generation of the second and third pulses, then the auxiliary circuit 110 may be uninvolved, not contribute, and/or not participate in the generation of the third pulse of the output signal DAT_OUT corresponding to the third pulse of the source signal DAT. Accordingly, whether the auxiliary circuit 110 contributes to or participates in the generation of a pulse of two consecutive pulses may depend and/or be based on whether the primary circuit 108 generates two consecutive pulses at the same or different voltage levels, at voltage levels that correspond to the same or different logic levels, and/or whether the primary circuit 108 generates the voltage of the output signal DAT_OUT to cross the associated threshold level V_{TH2} during generation of and/or in order to generate the two consecutive pulses. The auxiliary circuit 110 may be selectively used in this manner to participate or not participate in the generation of each of the pulses of the output signal DAT_OUT.

Whether the auxiliary circuit 110 participates or not in the generation of a pulse of the output signal DAT_OUT may affect or determine an overall output driver impedance of the output driver circuit 106. Each of the primary circuit 108 and the auxiliary circuit 110 may exhibit their own respective driver impedances when operating or participating in a pull-up or push-down operation. Accordingly, when the auxiliary circuit 110 is participating in a pull-up or push-down operation, its driver impedance may contribute, in combination with the impedance of the primary circuit 108, to the overall or effective impedance of the output driver circuit 106. Conversely, when the auxiliary circuit 110 is not participating in either a pull-up or a push-down operation, the auxiliary circuit 110 may have no or a negligible effect on the overall impedance of the output driver circuit 108. That is, the overall impedance may be solely or almost solely determined by the impedance of the primary circuit 108.

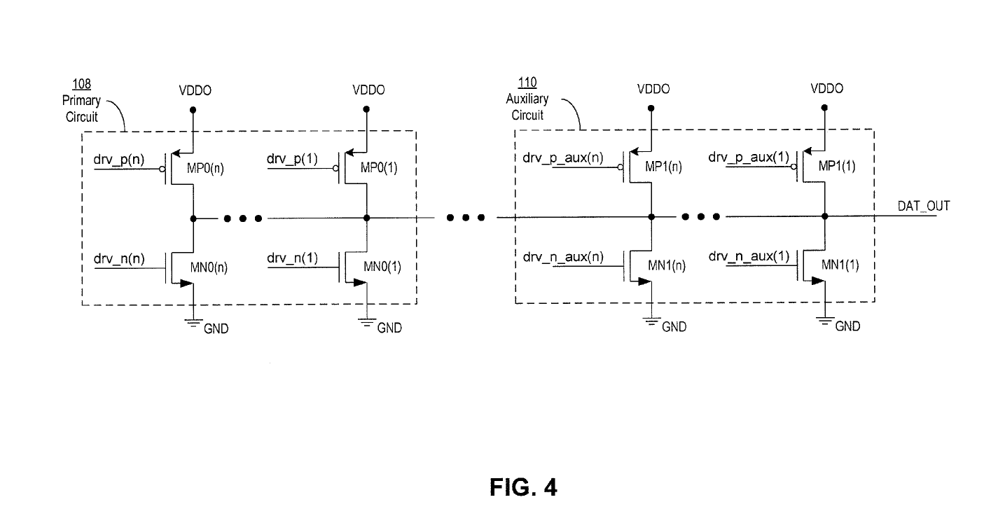

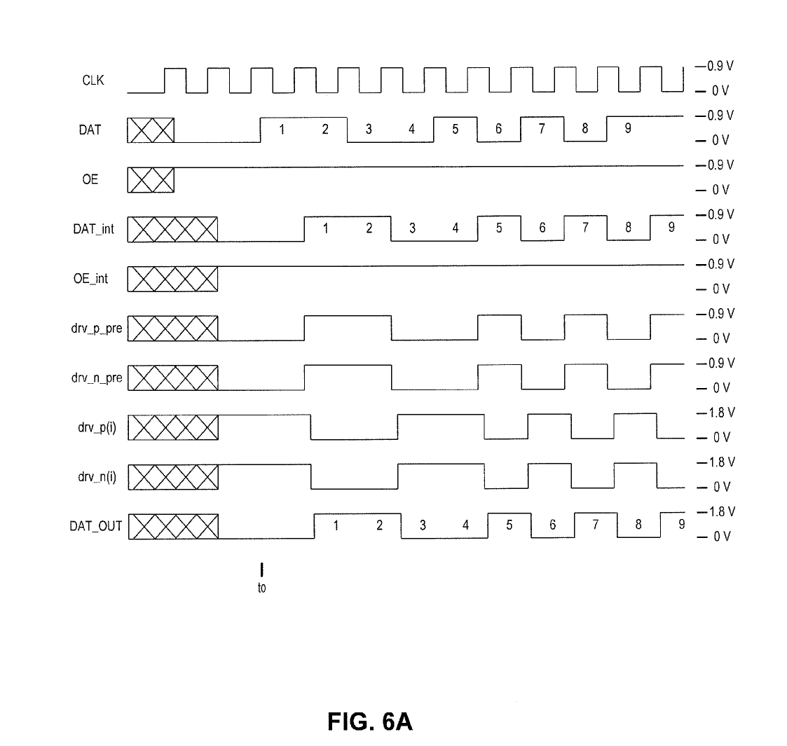

As shown in further detail below with reference to FIGS. 3 and 5, the primary circuit 108 and the auxiliary circuit 110 may form a parallel connection with each other. As such, on one hand, when the auxiliary circuit 110 is participating in the generation of a pulse of the output signal DAT_OUT, the overall impedance of the output driver circuit 106 may be the parallel combination of the impedance of the primary circuit 108 and the impedance of the auxiliary circuit 110. On the other hand, when the auxiliary circuit 110 is not participating in the generation of the output signal DAT_OUT, the overall impedance of the output driver circuit may be the impedance of the primary circuit 108. Due to the parallel connection, the overall impedance of the output driver circuit 106 may be lower when the auxiliary circuit 110 is participating than when it is not participating.

Where generating two consecutive pulses of the output signal DAT_OUT involves a crossing of the threshold level V_{TH2}, such as to generate the pulses to correspond to different logic levels, there may be a significantly larger voltage swing compared to where generating two signals does not involve the threshold level V_{TH2} being crossed, such as to generate the pulses to correspond to the same logic levels. When the threshold level V_{TH2} is crossed during generation of consecutive pulses, the large voltage swing (e.g., the voltage of the output signal DAT_OUT transitioning from the high voltage level V_{H2} to the low voltage level V_{L2} or vice versa) may correspond to a relatively high frequency component of the signal, and the threshold level V_{TH2} not being crossed may correspond to a relatively low frequency component of the output signal DAT_OUT. High frequency components may have a tendency to be attenuated more than their low frequency counterparts. By activating the auxiliary circuit 110 when the threshold level V_{TH2} is crossed, the overall impedance of the output driver circuit 106 may be lowered for these high frequency situations, which in turn may compensate for attenuation experienced. Such a configuration of selective operation of the auxiliary circuit 110 may allow for optimum driver impedance and minimized inter-symbol interference and noise.

Referring back to FIG. 1, the driver control circuit 104 may be configured to control whether the auxiliary circuit 110 contributes to and/or participates in the generation of a given pulse of the output signal DAT_OUT through generation of the auxiliary driver control signal drv_aux. Depending on the level of the auxiliary driver control signal drv_aux, the auxiliary circuit 110 may be activated to contribute to and/or participate in the generation of the given pulse or deactivated to not contribute to and/or participate in the generation of the given pulse. As described in further detail below, the driver control circuit 104 may be configured to analyze and/or compare logic levels of consecutive pulses of the source signal DAT to determine whether to activate or deactivate the auxiliary circuit 110.

In a particular example configuration, the output driver circuit 106, including the primary circuit 108 and the auxiliary circuit 110, may be a voltage mode driver circuit that is configured to drive the output node OUT according to voltage levels, such as a high voltage level and a low voltage level. An example voltage mode driver circuit is a push-pull circuit that is activated to pull up the voltage on the output node OUT to the high voltage level or push down the voltage on the output node OUT to the low voltage level. For these configurations, each of the driver control signals may include at least two control signals, including a pull-up control signal to control the pull-up operation of an associated push-pull circuit, and a push-down control signal to control the push-down operation of the associated push-pull circuit.

FIG. 3 shows an example push-pull circuit configuration for each of the primary circuit 108 and the auxiliary circuit 110. Each push-pull circuit may include a pull-up portion, which may include pull-up transistor (e.g., a p-channel metal-oxide semiconductor field-effect transistor (PMOS transistor)) and a push-down portion, which may include a push-down transistor (e.g, an n-channel metal-oxide semiconductor field-effect transistor (NMOS transistor)). Accordingly, the primary circuit 108 may include a primary PMOS transistor MP0 and a primary NMOS transistor MN0. The primary PMOS transistor MP0 may include a source terminal coupled to a source or supply voltage VDDO, a drain terminal coupled to the output node OUT, and a gate terminal configured to receive a primary pull-up control signal drv_p. The primary NMOS transistor MN0 may include a source terminal coupled to ground (GND), a drain terminal coupled to the output node OUT, and a gate terminal configured to receive a primary push-down control signal drv_n.

In operation, when the primary pull-up control signal drv_p is at a low level, the primary PMOS transistor MP0 is turned on, causing current to flow through the primary PMOS transistor MP0 and the primary PMOS transistor MP0 to pull up the voltage on the output node OUT to the level of the source voltage VDDO (i.e., the high voltage level). Conversely, when the primary pull-up control signal drv_p is at a high level, the primary PMOS transistor MP0 is turned off, causing the primary PMOS transistor MP0 to be uninvolved or not participate in setting the voltage level on the output node OUT.

Similarly, in operation, when the primary push-down control signal drv_p is at a high level, the primary NMOS transistor MN0 is turned on, causing current to flow through the primary NMOS transistor MN0 and the primary NMOS transistor MN0 to push down the voltage on the output node OUT to ground (GND) (i.e., the low voltage level). Conversely, when the primary push-down control signal drv_n is at a low level, the primary NMOS transistor MN0 is turned off, causing the primary NMOS transistor MN0 to be uninvolved or not participate in setting the voltage level on the output node OUT.

In general, the primary PMOS transistor MP0 and the primary NMOS transistor MN0 may operate such that they are not in contention with each other. That is, when the primary PMOS transistor MP0 is turned on to pull up the voltage on the output node OUT, the primary NMOS transistor MN0 is turned off so that it is not simultaneously pushing down the voltage on the output node OUT. Likewise, when the primary NMOS transistor MN0 is pushing down the voltage on the output node OUT, the primary PMOS transistor MP0 is turned off so that it is not simultaneously pulling up the voltage on the output node OUT.

In addition, the primary circuit 108 may be considered to be activated when either the primary PMOS transistor MP0 is turned on to draw current and pull up the voltage on the output node OUT or the primary NMOS transistor MN0 is turned on to drawn current and push down the voltage on the output node OUT. Conversely, the primary circuit 108 may be considered to be deactivated when both the primary PMOS transistor MP0 and the primary NMOS transistor MN0 are turned off such that neither are drawing current and participate in respective pulling up and pushing down operations.

The push-pull configuration of the auxiliary circuit 110 may be similar to that of the primary circuit 108. That is, the auxiliary circuit 110 may include an auxiliary PMOS transistor MP1 and an auxiliary NMOS transistor MN1. The auxiliary PMOS transistor MP1 may include a source terminal coupled to a source voltage VDDO, a drain terminal coupled to the output node OUT, and a gate terminal configured to receive an auxiliary pull-up control signal drv_p_aux. The auxiliary NMOS transistor MN1 may include a source terminal coupled to ground (GND), a drain terminal coupled to the output node OUT, and a gate terminal configured to receive an auxiliary push-down control signal drv_n.

In operation, when the auxiliary pull-up control signal drv_p_aux is at a low level, the auxiliary PMOS transistor MP1 is turned on, causing current to flow through the auxiliary PMOS transistor MP1 and the auxiliary PMOS transistor MP1 to pull up the voltage on the output node OUT to the level of the source voltage VDDO. Conversely, when the auxiliary pull-up control signal drv_p_aux is at a high level, the auxiliary PMOS transistor MP1 is turned off, causing the auxiliary PMOS transistor MP1 to be uninvolved or not participate in setting the voltage level on the output node OUT.

Similarly, in operation, when the auxiliary push-down control signal drv_p_aux is at a high level, the auxiliary NMOS transistor MN1 is turned on, causing current to flow through the auxiliary NMOS transistor MN1 and the auxiliary NMOS transistor MN1 to push down the voltage on the output node OUT to ground GND. Conversely, when the auxiliary push-down control signal drv_n_aux is at a low level, the auxiliary NMOS transistor MN1 is turned off, causing the auxiliary NMOS transistor MN1 to be uninvolved or not participate in setting the voltage level on the output node OUT.

Similar to the primary PMOS and NMOS transistors MP0, MN0, the auxiliary PMOS transistor MP1 and the auxiliary NMOS transistor MN1 may operate such that they are not in contention with each other. That is, when the auxiliary PMOS transistor MP1 is turned on to pull up the voltage on the output node OUT, then the auxiliary NMOS transistor MN1 is turned off so that it is not simultaneously pushing down the voltage on the output node OUT. Likewise, when the auxiliary NMOS transistor MN1 is pushing down the voltage on the output node OUT, the auxiliary PMOS transistor MP1 is turned off so that it is not simultaneously pulling up the voltage on the output node OUT.

In addition, the auxiliary circuit 110 may be considered to be activated when either the auxiliary PMOS transistor MP1 is turned on to draw current and pull up the voltage on the output node OUT or the auxiliary NMOS transistor MN1 is turned on to drawn current and push down the voltage on the output node OUT. Conversely, the auxiliary circuit 110 may be considered to be deactivated when both the primary PMOS transistor MP0 and the primary NMOS transistor MN0 are turned off such that neither are drawing current and involved or participate in respective pulling up and pushing down operations.

Also, each of the transistors MP0, MN0, MP1, MN1 may be implemented as a single transistor or a plurality of parallel-connected transistors, which may be referred to as a bank or group of transistors. As shown in FIG. 3, the symbol “<n:1>” is appended to each of the primary and auxiliary pull-up and push-down control signals drv_p, drv_n, drv_p_aux, drv_n_aux to indicate that each of the control signals drv_p, drv_n, drv_p_aux, drv_n_aux includes an n-number control signals, with each being sent to one of an n-number of transistors in a respective bank.

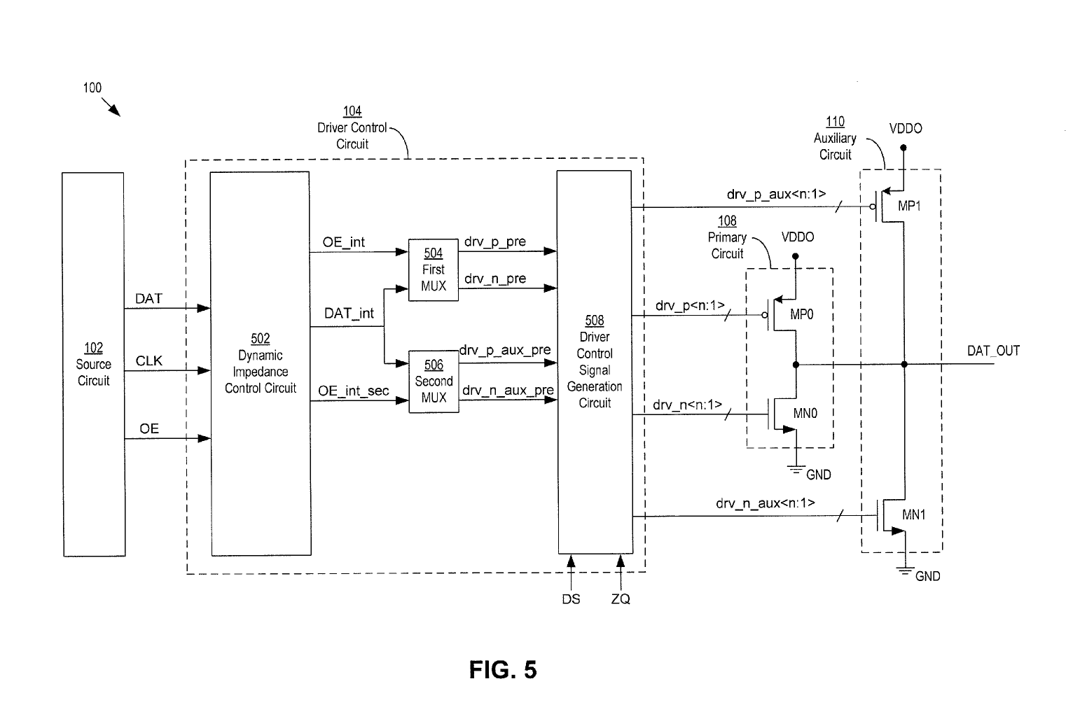

FIG. 4 shows a circuit schematic diagram of the transistors banks for each of the first and auxiliary PMOS and NMOS transistors MP0, MN0, MP1, MN1 in further detail. As shown in FIG. 4, the primary PMOS transistor MP0 includes an n-number of parallel-connected transistors MP0(1) to MP0(n), each configured to receive at its gate terminal a respective one of the n-number of primary pull-up control signals drv_p(1) to drv_p(n); the primary NMOS transistor MN0 includes an n-number of parallel-connected transistors MN0(1) to MN0(n), each configured to receive at its gate terminal a respective one of the n-number of primary push-down control signals drv_n(1) to drv_n(n); the auxiliary PMOS transistor MP1 includes an n-number of parallel-connected transistors MP1(1) to MP1(n), each configured to receive at its gate terminal a respective one of the n-number of auxiliary pull-up control signals drv_p_aux(1) to drv_p_aux(n); and the auxiliary NMOS transistor MN1 includes an n-number of parallel-connected transistors MN1(1) to MN1(n), each configured to receive at its gate terminal a respective one of the n-number of primary push-down control signals drv_p_aux(1) to drv_p_aux(n).

In general, the number n may be an integer of one or more. Also, in some example configurations, the number n may be the same for each of the transistor banks MP0, MN0, MP1, MN1, while in other example configurations, the number n may be different for two or more of the transistor banks MP0, MN0, MP1, MN1.

FIG. 5 shows a block diagram of an example configuration of the driver control circuit 104 in further detail. As shown in FIG. 5, the example configuration may include a dynamic impedance control circuit 502, a first multiplexer (MUX) 504, a second multiplexer 506, and a driver control signal generation circuit 508.

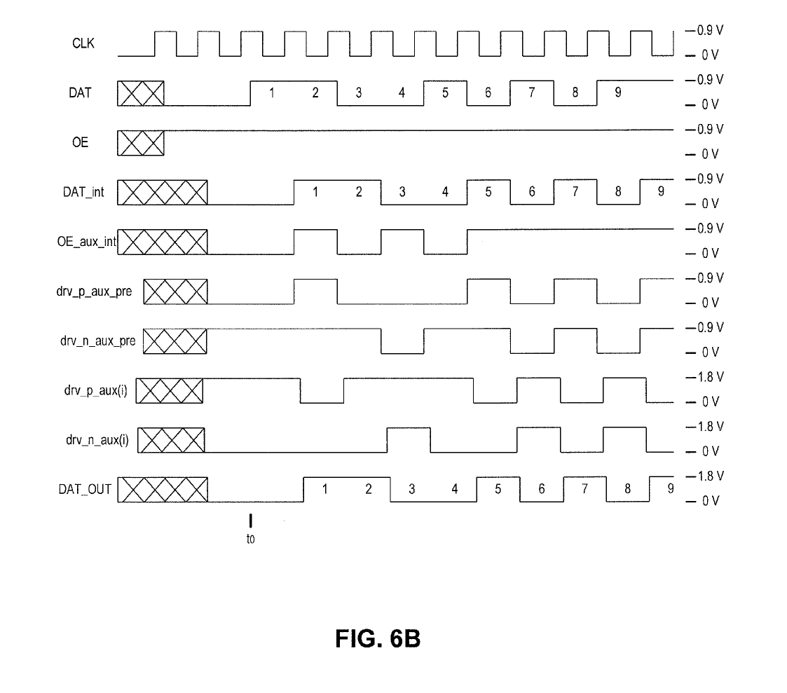

The dynamic impedance control circuit 502 may be configured to receive the source signal DAT, the clock signal CLK, and the enable signal OE from the source circuit 102. Based on the levels of these signals, the dynamic impedance control circuit 502 may generate and output an intermediate source signal DAT_int, a primary intermediate enable signal OE_int, and an auxiliary intermediate enable signal OE_int_aux at certain levels in order to activate and deactivate each of the primary and auxiliary circuits 108, 110. In particular, the levels at which the dynamic impedance control circuit 502 may be configured to generate the auxiliary intermediate enable signal OE_int_aux may depend on whether the dynamic impedance control circuit 502 wants the auxiliary circuit 110 to participate in generation of a pulse of the output signal DAT. For example, as previously described, if two consecutive pulses of the source signal DAT correspond to different logic levels, then the dynamic impedance control circuit 502 may generate the auxiliary intermediate enable signal OE_int_aux at one level (e.g., a high level) to indicate that it wants the auxiliary circuit 110 to participate in generation of the latter of the two corresponding consecutive pulses of the output signal DAT_OUT. Alternatively, if two consecutive pulses of the source signal DAT correspond to the same logic level, then the dynamic impedance control circuit 502 may generate the auxiliary intermediate enable signal OE_int_aux at another level (e.g., a low level) to indicate that it wants the auxiliary circuit 110 to not participate in the latter of the two corresponding consecutive pulses of the output data signal DAT_OUT. In one example configuration, as described in further detail below with reference to FIGS. 6A and 6B, the dynamic impedance control circuit 502 may output the auxiliary intermediate enable signal OE_int_aux at a high level to indicate that it wants to the auxiliary circuit 110 to participate, and at a low level to indicate that it wants the auxiliary circuit 110 not to participate, although other configurations are possible.

As shown in FIG. 5, the first MUX 504 may be configured to receive the intermediate source signal DAT_int and the primary intermediate enable signal OE_int. Based on the levels of the intermediate source signal DAT_int and the primary intermediate enable signal OE_int, the first MUX 504 may be configured to output a primary pull-up pre-control signal drv_p_pre and a primary push-down pre-control signal drv_n_pre at certain levels in order to have the primary PMOS transistor MP0 and the primary NMOS transistor MN0 of the primary circuit 108 operate as desired.

Additionally, the second MUX 506 may be configured to receive the intermediate source signal DAT_int and the auxiliary intermediate enable signal OE_int_aux. Based on the levels of the intermediate source signal DAT_int and the auxiliary intermediate enable signal OE_int_aux, the second MUX 506 may be configured to output an auxiliary pull-up pre-control signal drv_p_aux_pre and an auxiliary push-down pre-control signal drv_n_aux_pre at certain levels in order to have the auxiliary PMOS transistor MP1 and the auxiliary NMOS transistor MN1 of the primary circuit 110 operate as desired.

The driver control signal generation circuit may be configured to receive the pre-control signals drv_p_pre, drv_n_pre, drv_p_aux_pre, drv_n_aux_pre, and generate the control signals drv_p, drv_n, drv_p_aux, drv_n_aux based on the levels of the pre-control signals drv_p_pre, drv_n_pre, drv_p_aux_pre, drv_n_aux_pre. The driver control signal generation circuit 508 may include certain circuit components used to convert or condition the pre-control signals into control signals that can adequately drive the primary and auxiliary push-pull circuits 108, 110. Example circuit components may include level-shifter circuits, drive control circuits, and/or pre-driver circuitry.

Also, as shown in FIG. 5 (and in FIGS. 1 and 3 as well), the driver control signal generation circuit 508 may be configured to receive a drive strength control signal (DS) and an impedance control signal (ZQ). The driver strength and impedance control signals DS, ZQ may each be analog signals or digital signals (e.g., m-bit signals) and/or may each include a single signal or multiple signals. In addition, the driver strength and impedance control signals DS, ZQ may be generated as part of a calibration process that determines and/or characterizes certain process, voltage, temperature (PVT) conditions and/or characteristics associated with the circuit system 100. The driver strength and impedance control signals DS, ZQ may be used to compensate for variations in the PVT conditions and/or characteristics in order to ensure that a desired drive strength or output impedance is achieved.

For example, the transistors MP0, MN0, MP1, MN1 may each have an effective impedance that is exhibited when performing their respective pull-up or push-down operations, and it may be desirable for the transistors MP0, MN0, MP1, MN1 to perform their respective pull-up or push-down operations with a desired or target effective impedance. The respective effective impedances of each of the transistors MP0, MN0, MP1, MN1 may depend on the number of transistors within their respective banks that are turned on during the respective pull-up or push-down operations. Depending on the particular PVT conditions and/or characteristics determined by the calibration process, it may be desirable for a given transistor bank to have all or less than all of its transistors turned on when the transistor bank is performing a pull-up or push-down operation so that the transistor bank performs the pull-up or push-down operation with the desired or target effective impedance. The drive strength control signal DS and/or the impedance control signal ZQ may be used to determine how many and/or which transistors in a given bank to turn on for a pull-up or push-down operation. As described in further detail below, if a given one of the transistors MP0, MN0, MP1, MN1 is to be turned on to participate in generation of a pulse of the output signal DAT_OUT, then at least one transistor within the associated bank is turned on. The total number of transistors in the bank that are turned on, or how many other transistors in addition to the one, may depend on the drive strength control signal DS and/or the impedance control signal ZQ.

Operation of the circuit components shown in FIG. 5 is described with reference to FIGS. 6A and 6B, which show timing diagrams of the various signals generated with the circuit components shown in FIG. 5. For clarity, generation of the signals to control operation of the primary circuit 108 is described with reference FIG. 6A, and generation of the signals to control operation of the auxiliary circuit 110 is described with reference to FIG. 6B.

Preliminarily, it is noted that in the example timing diagrams of FIGS. 6A and 6B, the signals generated to control operation of the primary circuit 108 and the auxiliary circuit 110 are with reference to a source signal DAT output from the source circuit 102. FIGS. 6A and 6B each show the same nine pulses of the source signal DAT, which are labeled “1” to “9” in each of FIGS. 6A and 6B. In addition, the clock signal CLK has a clock rate that is twice the rate of the source signal DAT. Otherwise stated, a given pulse of the source signal DAT extends over a full period or clock cycle of the clock signal CLK. Additionally, FIGS. 6A and 6B show each of the signals as transitioning between a high level of 0.9 Volts (V) and low level of 0 V, or a high level of 1.8 V and a low level of 0 V. These voltage level values are merely examples and other high and/or low voltage levels may be possible.

In addition, the waveform of the output signal DAT_OUT directly matches or tracks the source signal DAT, both in terms of pulse levels and frequency (rate). FIGS. 6A and 6B show the nine corresponding pulses of the output signal DAT_OUT, which are similarly labeled “1” to “9.” Accordingly, if a pulse of the source signal DAT is at a high level, a corresponding pulse of the output signal DAT_OUT is generated at a high level. Likewise, if a pulse of the source signal DAT is at a low level, a corresponding pulse of the output signal DAT_OUT is generated at a low level. Other example configurations that instead utilize an inverse relationship between the source signal DAT and the output signal DAT_OUT may be possible. That is, if a pulse of the source signal DAT is at a high level, a corresponding pulse of the output signal DAT_OUT is generated at a low level, and if a pulse of the source signal DAT is at a low level, a corresponding pulse of the output signal DAT_OUT is generated at a high level. In general, the output signal DAT_OUT is generated so that there is a relationship (directly or inversely) between the levels of the pulses of the output signal DAT_OUT and their corresponding pulses of the source signal DAT. Accordingly, in the situation where the source signal DAT and the output signal DAT_OUT are data signals, the bit sequence represented by the pulses of the output signal DAT_OUT matches and/or corresponds to the bit sequence represented by the pulses of the source signal DAT.

Lastly to preliminarily note, as shown in FIGS. 6A and 6B, the waveform of the intermediate source signal DAT_int directly tracks or matches the waveform of the source signal DAT, but with a delay of one clock cycle. FIGS. 6A and 6B show the nine pulses of the intermediate source signal DAT_int corresponding to the nine pulses of the source signal DAT being labeled as “1” through “9.”

In general, the dynamic impedance control circuit 502, the first multiplexer 504, and the driver control signal generation circuit 508 may be configured to output their respective signals DAT_int, OE_int, OE_int_aux, drv_p_pre, drv_n_pre, drv_p, drv_n, drv_p_aux_pre, drv_n_aux_pre, drv_p_aux, and drv_n_aux at appropriate levels to cause the primary circuit 108 to perform pull-up and push-down operations in order to generate pulses of the output signal DAT_OUT at levels corresponding to the levels of the corresponding pulses of the source signal DAT. The levels (e.g., high and low levels) at which the dynamic impedance controls circuit 502, the first multiplexer 504, and the driver control signal generation circuit 508 are configured to output their respective signals may depend on their particular configurations.

The example signaling shown in FIGS. 6A and 6B is for an example configuration where: (a) the pulse levels of the pulses of the output signal DAT_OUT directly track and/or correspond to the pulse levels of the pulses of the source signal DAT; (b) the driver control signal generation circuitry 508 generates its outputs as inverted versions of its inputs; and (c) the dynamic impedance control circuit 502 is configured to: (i) output the intermediate primary enable auxiliary enable signal OE_int at a high level to indicate it wants the primary circuit 108 to be activated/enabled; (ii) output the auxiliary intermediate enable signal OE_int_aux at a high level to indicate it wants the auxiliary circuit 110 to be activated/enabled; and (iii) output the intermediate source signal DAT_int at levels that directly track and/or correspond to the pulse levels of the source signal DAT. For other example configurations, the dynamic impedance control circuit 502, the first multiplexer 504, and the driver control signal generation circuit 508 may be configured to generate their respective signals DAT_int, OE_int, OE_int_aux, drv_p_pre, drv_n_pre, drv_p, drv_n, drv_p_aux_pre, drv_n_aux_pre, drv_p_aux, and drv_n_aux at other levels in order to cause the primary circuit 108 to perform pull-up and push-down operations as desired.

In addition, FIG. 6A shows an ith primary pull-up control signal drv_p(i) and an ith primary push-down control signal drv_n(i) being generated. The ith primary pull-up control signal drv_p(i) may be representative of at least one of the n-number of primary pull-up control signals drv_p<n:1> responsive to the primary pull-up pre-control signal drv_p_pre, and the ith push-down control signal drv_n(i) may be representative of at least one of the n-number of primary push-down control signals drv_n<n:1> responsive to the primary push-down pre-control signal drv_n_pre, respectively. Accordingly, the driver control signal generation circuit 508 may be configured to generate the ith primary pull-up control signal drv_(i) and the ith primary push-down control signal drv_n(i) as inverted versions of the primary pull-up pre-control signal drv_p_pre and the primary push-down pre-control signal drv_n_pre, respectively.

Similarly, FIG. 6B shows an ith auxiliary pull-up control signal drv_p_aux(i) and an ith auxiliary push-down control signal drv_n_aux(i) being generated. The ith auxiliary pull-up control signal drv_p_aux(i) may be representative of at least one of the n-number of auxiliary pull-up control signals drv_p_aux<n:1> responsive to the auxiliary pull-up pre-control signal drv_p_aux_pre, and the ith auxiliary push-down control signal drv_n_aux(i) may be representative of at least one of the n-number of auxiliary push-down control signals drv_n_aux<n:1> responsive to the auxiliary push-down pre-control signal drv_n_aux_pre. Accordingly, the driver control signal generation circuit 508 may be configured to generate the ith auxiliary pull-up control signal drv_p_aux(i) and the ith auxiliary push-down control signal drv_n_aux(i) as inverted versions of the auxiliary pull-up pre-control signal drv_p_aux_pre and the auxiliary push-down pre-control signal drv_n_aux_pre, respectively.

Also, for some example configurations, in addition to being inverted, the driver control signal generation circuit 508 may generate the ith primary control signals drv_p(i), drv_n(i) and the ith auxiliary control signal drv_p_aux(i), drv_n_aux(i) in an increased or up-shifted voltage domain compared to the voltage domain in which the primary and auxiliary pre-control signals drv_p_pre, drv_n_pre, drv_p_aux_pre, drv_n_aux_pre are generated, as indicated by the high level of the ith primary and auxiliary control signals drv_p(i), drv_n(i), drv_p_aux(i), and drv_n_aux(i) being at 1.8 V compared to the high level of the primary and auxiliary pre-control signals drv_p_pre, drv_n_pre, drv_p_pre_aux, and drv_n_pre_aux being at 0.9 V. In other example configuration, the change in voltage domain may not be performed, or may be performed at a different stage or with different components of the circuit system 100, such as with the first and second multiplexers 504, 506, for example.

Referring particularly to FIG. 6A, when the source circuit 102 wants the source signal DAT to be transmitted, it may begin outputting the enable signal OE at the activation level (e.g., by pulling the enable signal OE to a high voltage level). For some example configurations, the source circuit 102 may be configured to output the enable signal OE at the activation level before it outputs the initial or first pulse of the source signal DAT. This is shown in FIG. 6A, where time to denotes the time that the source circuit 102 outputs the first pulse of the source signal DAT, and the enable signal OE is pulled high before time to.

In response to a given pulse of the source signal DAT output at the high voltage level (such as the first, second, fifth, seventh, and ninth pulses shown in FIG. 6A), the dynamic impedance control circuit 502 may be configured to generate a corresponding pulse of the intermediate data signal DAT_int at a high level, indicating that the primary circuit 108 is to perform a pull-up operation to generate the corresponding pulse of the output signal DAT_OUT. In response to the intermediate data signal DAT_int at a high level and the intermediate enable signal OE_int at a high level, the first multiplexer 604 may be configured to generate the primary pull-up pre-control signal drv_p_pre and the primary push-down pre-control signal drv_n_pre each at high levels so that the driver control signal generation circuit 508 outputs the ith primary pull-up control signal drv_p(i) and the ith primary push-down control signal drv_n(i) each at low levels to cause the primary circuit 108 to perform a pull-up operation.

Similarly, in response to a given pulse of the source signal DAT at the low level (such as the third, fourth, sixth, and eighth pulses shown in FIG. 6A), the dynamic impedance control circuit 502 may be configured to generate a corresponding pulse of the intermediate data signal DAT_in at a low level, indicating that the primary circuit 108 is to perform a push-down operation to generate the corresponding pulse of the output signal DAT_OUT. In response to the intermediate data signal DAT_int at a low level and the intermediate enable signal OE_int at a high level, the first multiplexer 604 may be configured to generate the primary pull-up pre-control signal drv_p_pre and the primary push-down pre-control signal drv_n_pre each at low levels so that the driver control signal generation circuit 508 outputs the ith primary pull-up control signal drv_p(i) and the ith primary push-down control signal drv_n(i) each at high levels to cause the primary circuit 108 to perform a push-down operation.

Control of the auxiliary circuit 110 is now described with reference to FIG. 6B. As previously described, for generation of two consecutive pulses, if the logic level of the second pulse is different than the logic level of the first pulse and/or if the primary circuit 108 generates the voltage of the output signal DAT_OUT to cross a threshold level during generation of the consecutive pulses, then the auxiliary circuit 110 may participate in the generation of the second pulse. Conversely, if the logic levels of the two consecutive pulses are the same and/or if primary circuit generates the voltage of the output signal DAT_OUT to not cross the threshold level during generation of the consecutive pulses, then the auxiliary circuit 110 may not participate in the generation of the second pulse. From a pull-up/push-down perspective, the selective operation of the auxiliary circuit 110 is performed in eight different situations with respect to two consecutive pulses.

In a first situation, the primary circuit 108 is performing pull-up operations to generate both a first pulse and a second, subsequent pulse, and the auxiliary circuit 110 is deactivated to not participate in generation of both the first pulse and the second pulse. To do so, the driver control signal generation circuit 508 may generate the ith auxiliary pull-up control signal drv_p_aux(i) at a high level so that the ith auxiliary PMOS transistor MP1(i) is turned off during generation of both the first pulse and the second pulse. In addition, the driver control signal generation circuit 508 may generate the ith auxiliary push-down control signal drv_n_aux(i) at a low level so that the ith auxiliary NMOS transistor MN1(i) is turned off during generation of both the first pulse and the second pulse.

In a second situation, the primary circuit 108 is performing pull-up operations to generate both the first pulse and the second pulse, and the auxiliary circuit 110 is activated to participate in the pulling up of the first pulse and deactivated to not participate in the pulling up of the second pulse. To do so, the driver control signal generation circuit 508 may generate the ith auxiliary pull-up control signal drv_p_aux(i) at a low level so that the ith auxiliary PMOS transistor MP1(i) is turned on to participate in the generation of the first pulse. The driver control signal generation circuit 508 may then generate the ith auxiliary pull-up signal drv_p_aux(i) at a high level so that the ith auxiliary PMOS transistor MP1(i) is turned off during generation of the second pulse. In addition, the driver control signal generation circuit 508 may generate the ith auxiliary push-down control signal drv_n_aux(i) at a low level so that the ith auxiliary NMOS transistor MN1(i) is turned off during generation of both the first pulse and the second pulse.

In a third situation, the primary circuit 108 is performing a pull-up operation to generate the first pulse and a push-down operation to generate the second pulse, and the auxiliary circuit 110 is deactivated to not participate in the pulling up of the first pulse and activated to participate in the pushing down of the second pulse. To do so, the driver control signal generation circuit 508 may generate the ith auxiliary pull-up control signal drv_p_aux(i) at a high level so that the ith auxiliary PMOS transistor MP1(i) is turned off during generation of the first pulse and the second pulse. Additionally, the driver control signal generation circuit 508 may generate the ith auxiliary push-down control signal drv_n_aux(i) at a low level to turn off the ith auxiliary NMOS transistor MN1(i) during generation of the first pulse. Then, for generation of the second pulse, the driver control signal generation circuit 508 may generate the ith auxiliary push-down control signal drv_n_aux(i) at a high level to turn on the ith auxiliary NMOS transistor MN1(i) so that the ith auxiliary NMOS transistor MN1(i) participates in the push down operation to generate the second pulse.

In a fourth situation, the primary circuit 108 is performing a pull-up operation to generate the first pulse and a push-down operation to generate the second pulse, and the auxiliary circuit 110 is activated to participate in the pulling up of the first pulse and activated to participate in the pulling down of the second pulse. To do so, for generation of the first pulse, the driver control signal generation circuit 508 may generate the ith auxiliary pull-up control signal drv_p_aux(i) at a low level so that the ith auxiliary PMOS transistor MP1(i) is turned on to participate in the pulling up operation. Then, for generation of the second pulse, the driver control signal generation circuit 508 may generate the ith auxiliary pull-up control signal drv_p_aux(i) at a high level to turn off the ith auxiliary PMOS transistor MP1(i) for the push down operation. Additionally, for generation of the first pulse, the driver control signal generation circuit 508 may generate the ith auxiliary push-down control signal drv_n_aux(i) at a low level to turn off the ith auxiliary NMOS transistor MN1(i) for the pull up operation. Then, for generation of the second pulse, the driver control signal generation circuit 508 may generate the ith auxiliary push-down control signal drv_n_aux(i) at a high level to turn on the ith auxiliary NMOS transistor MN1(i) so that the ith auxiliary NMOS transistor MN1(i) participates in the pulling down operation to generate the second pulse.

In a fifth situation, the primary circuit 108 is performing push-down operations to generate both the first pulse and the second pulse, and the auxiliary circuit 110 is deactivated during generation of both the first pulse and the second pulse. To do so, the driver control signal generation circuit 508 may generate the ith auxiliary pull-up control signal drv_p_aux(i) at a high level so that the ith auxiliary PMOS transistor MP1(i) is turned off during generation of both the first pulse and the second pulse. In addition, the driver control signal generation circuit 508 may generate the ith auxiliary push-down control signal drv_n_aux(i) at a low level so that the ith auxiliary NMOS transistor MN (i) is turned off during generation of both the first pulse and the second pulse.

In a sixth situation, the primary circuit 108 is performing push-up operations to generate both the first pulse and the second, and the auxiliary circuit 110 is activated to participate in the pushing down of the first pulse and deactivated to not participate in the pushing down of the second pulse. To do so, the driver control signal generation circuit 508 may generate the ith auxiliary pull-up control signal drv_p_aux(i) at a high level so that the ith auxiliary PMOS transistor MP1(i) is turned off during generation of the first pulse and the second pulse. In addition, the driver control signal generation circuit 508 may generate the ith auxiliary push-down control signal drv_n_aux(i) at a high level so that the ith auxiliary NMOS transistor MN1(i) is turned on to participate in the generation of the first pulse. However, the driver control signal generation circuit 508 may then generate the ith auxiliary push-down control signal drv_n_aux(i) at a low level so that the ith auxiliary NMOS transistor MN1(i) is turned off during generation of the second pulse.

In a seventh situation, the primary circuit 108 is performing a push-down operation to generate the first pulse and a pull-up operation to generate the second pulse, and the auxiliary circuit 110 is deactivated to not participate in the pulling up of the first pulse and activated to participate in the pulling up of the second pulse. To do so, the driver control signal generation circuit 508 may generate the ith auxiliary pull-up control signal drv_p_aux(i) at a high level so that the ith auxiliary PMOS transistor MP1(i) is turned off during generation of the first pulse. The driver control signal generation circuit 508 may then generate the ith auxiliary pull-up control signal drv_p_aux(i) at a low level so that the ith auxiliary PMOS transistor MP1(i) is turned on to participate in the generation of the second pulse. In addition, the driver control generation circuit 508 may generate the ith auxiliary push-down control signal drv_n_aux(i) at a low level so that the ith auxiliary NMOS transistor is turned off during generation of the first pulse and the second pulse.

In an eighth situation, the primary circuit 108 is performing a push-down operation to generate the first pulse and a pull-up operation to generate the second pulse, and the auxiliary circuit 110 is activated to participate in the pushing down of the first pulse and activated to participate in the pulling up of the second pulse. To do so, the driver control signal generation circuit 508 may generate the ith auxiliary pull-up control signal drv_p_aux(i) at a high level so that the ith auxiliary PMOS transistor MP1(i) is turned to participate in the generation of the first pulse. Then, the driver control signal generation circuit 508 generates the ith auxiliary pull-up control signal drv_p_aux(i) at a low level so that the ith auxiliary PMOS transistor MP1(i) is turned on to participate in the generation of the second pulse. In addition, the driver control signal generation circuit 508 may generate the ith auxiliary push-down control signal drv_n_aux(i) at a high level so that the ith auxiliary NMOS transistor MN1(i) is turned on to participate in the generation of the first pulse. Then, the driver control signal generation circuit 508 may generate the ith auxiliary push-down control signal drv_n_aux(i) at a low level so that the ith auxiliary NMOS transistor MN1(i) is turned off during generation of the second pulse.

These various situations in which selective participation of the auxiliary circuit 110 is performed to generate pulses of the output signal DAT_OUT is illustrated in FIG. 6B. For example, corresponding to the second situation, because the output signal DAT_OUT was low prior to generation of the first pulse, and because the first and second pulses of the source signal DAT are both at the high level, the auxiliary circuit 108 is to be activated to participate in generation of the first pulse and deactivated to not participate in generation of the second pulse. Accordingly, the driver control signal generation circuit 508 may generate the ith auxiliary control signal drv_n_aux(i) at a low level to turn on the ith auxiliary PMOS transistor MP1(i), and then generate the ith auxiliary control signal drv_p_aux(i) at a high level so that the ith auxiliary PMOS transistor MP1(i) is turned off during generation of the second pulse. In addition, the driver control signal generation circuit 508 may generate the ith auxiliary control signal drv_n_aux(i) at a low level so that the ith auxiliary NMOS transistor MN1(i) is turned off during generation of the first and second pulses.

As another example, corresponding to the third situation, the third pulse of the source signal DAT is at a low level, and so the threshold level will be crossed while pushing down the level of the output signal DAT_OUT from the high level to the low level to generate the third pulse. Accordingly, the auxiliary circuit 110 may transition from being deactivated during generation of the second pulse to being activated to participate in the pushing down of the third pulse. The driver control signal generation circuit 508 may generate the ith auxiliary pull-up control signal drv_p_aux(i) so that the ith auxiliary PMOS transistor MP1(i) remains turned off during generation of the third pulse. In addition, the driver control signal generation circuit 508 may transition the ith auxiliary push-down control signal drv_n_aux(i) to a high level so that the ith auxiliary NMOS transistor MN1(i) turns on to participate in the pushing down of the third pulse.

As another example, corresponding to the fourth situation, the fourth pulse of the source signal DAT is at a low level, the fifth pulse is at a high level, and the sixth pulse is at a low level. Accordingly, the auxiliary circuit 110 may be activated to perform a pull up operation to generate the fifth pulse, and remain activated but transition to performing a push down operation to generate the sixth pulse. To do so, the driver control signal generation circuit 508 may generate the ith auxiliary pull-up control signal drv_p_aux(i) at a low level so that ith auxiliary PMOS transistor MP1(i) turns on to participate in the pulling up of the fifth pulse, and then at a high level so that the ith auxiliary PMOS transistor MP1(i) is turned off during generation of the sixth pulse. Additionally, the driver control signal generation circuit may generate the ith auxiliary push-down control signal at a low level so that the ith auxiliary NMOS transistor MN1(i) is turned off during generation of the fifth pulse, and then at a high level so that the ith auxiliary NMOS transistor MN1(i) is turned on to participate in generation of the sixth pulse.

As previously described, for a given pulse of the source signal DAT at the high level, the dynamic impedance control circuit 502 may be configured to generate a corresponding pulse of the intermediate source signal DAT_int at a high level, and for the a given pulse of the source signal at the low level, the dynamic impedance control circuit 502 may be configured to generate a corresponding pulse of the intermediate data signal DAT_int at a low level. In addition, the dynamic impedance control circuit 502 may be configured to generate the auxiliary intermediate enable signal OE_int_aux at a high level to indicate that the auxiliary circuit 110 is to participate in the generation of a corresponding pulse of the output signal DAT_OUT, and may be configured to generate the auxiliary intermediate enable signal OE_int_aux at a low level to indicate that the auxiliary circuit is not to participate in the generation of a corresponding pulse of the output signal DAT_OUT.

Accordingly, there may be four operation conditions indicated by the combination of the intermediate source signal DAT_int and the auxiliary intermediate enable signal OE_int_aux: (1) the intermediate source signal DAT_int and the auxiliary intermediate enable signal OE_int_aux are both generated at high levels, indicating that the primary circuit 108 is to perform a pull-up operation to generate the corresponding pulse of the output signal DAT_OUT and the auxiliary circuit 110 is to participate in the pull-up operation; (2) the intermediate source signal DAT_int is generated at a high level and the auxiliary intermediate enable signal OE_int_aux is generated at a low level, indicating that the primary circuit 108 is to perform a pull-up operation to generate the corresponding pulse of the output signal DAT_OUT and the auxiliary circuit 110 is not to participate in the pull-up operation; (3) the intermediate source signal DAT_int is generated at a low level and the auxiliary intermediate enable signal OE_int_aux is generated at a high level, indicating that the primary circuit 108 is to perform a push-down operation to generate the corresponding pulse of the output signal DAT_OUT and the auxiliary circuit 110 is to participate in the push-down operation; and (4) the intermediate source signal DAT_int and the auxiliary intermediate enable signal OE_int_aux are both generated at low levels, indicating that the primary circuit 108 is to perform a push-down operation to generate the corresponding pulse of the output signal DAT_OUT and the auxiliary circuit 110 is not to participate in the push-down operation.

The second multiplexer 506 may be configured to respond to the intermediate source signal DAT_int and the auxiliary intermediate enable signal OE_int_aux at their respective levels by generating and outputting the auxiliary pull-up and push-down pre-control signals drv_p_aux_pre, drv_n_aux_pre at appropriate levels so that the auxiliary circuit 110 participates or does not participate in the pull-up or push-down operations, as indicated by the combination of the intermediate source signal DAT_int and the intermediate enable signal OE_int_aux.

In particular, in response to the intermediate source signal DAT_int and the auxiliary intermediate enable signal OE_int_aux both being at high levels, the second multiplexer 506 may generate the auxiliary pull-up and push-down pre-control signals drv_p_aux_pre, drv_n_aux_pre both at high levels, such that the driver control signal generation circuit 508 generates the ith auxiliary pull-up and push-down control signals drv_p_aux(i), drv_n_aux(i) both at low levels, which in turn causes the auxiliary circuit 110 to participate in the pulling up of the corresponding pulse. In addition, in response to the intermediate source signal DAT_int being at a high level and the auxiliary intermediate enable signal OE_int_aux being at a low level, the second multiplexer 506 may generate the auxiliary pull-up pre-control signal drv_p_aux_pre at a low level and the auxiliary push-down pre-control signal drv_n_aux_pre at a high level, such that the driver control signal generation circuit 508 generates the ith auxiliary pull-up control signal drv_p_aux(i) at a high level and the ith auxiliary push-down control signal drv_n_aux(i) at a low level, which in turn causes the auxiliary circuit 110 to not participate in the pulling up of the corresponding pulse. Also, in response to the intermediate source signal DAT_int being at a low level and the auxiliary intermediate enable signal OE_int_aux being at a high level, the second multiplexer 506 may generate the auxiliary pull-up and push-down pre-control signals drv_p_aux_pre, drv_n_aux_pre both at low levels, such that the driver control signal generation circuit 508 generates the ith auxiliary pull-up and push-down control signals drv_p_aux(i), drv_n_aux(i) both at high levels, which in turn causes the auxiliary circuit 110 to participate in pushing-down the corresponding pulse. Further, in response to the intermediate source signal DAT_int and the auxiliary intermediate enable signal OE_int_aux both being at low levels, the second multiplexer 506 may generate the auxiliary pull-up pre-control signal drv_p_aux_pre at a low level and the auxiliary push-down pre-control signal drv_n_aux_pre at a high level, such that the driver control signal generation circuit 508 generates the ith auxiliary pull-up control signal drv_p_aux(i) at a high level and the ith push-down control signals drv_n_aux(i) at a low level, which in turn causes the auxiliary circuit 110 to not participate in pushing down the corresponding pulse.

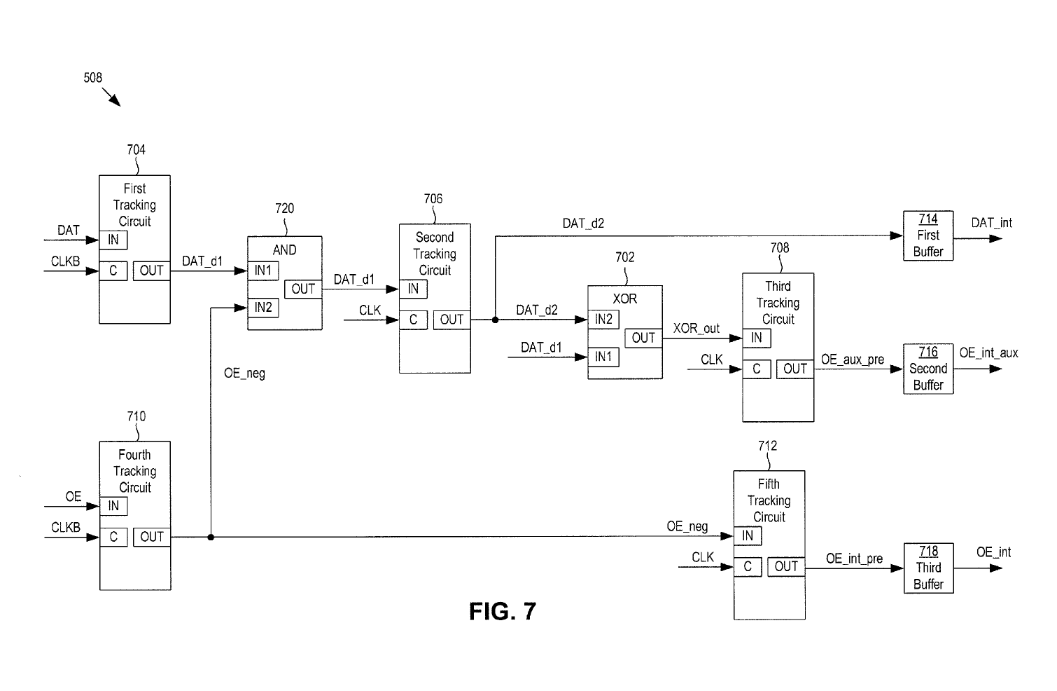

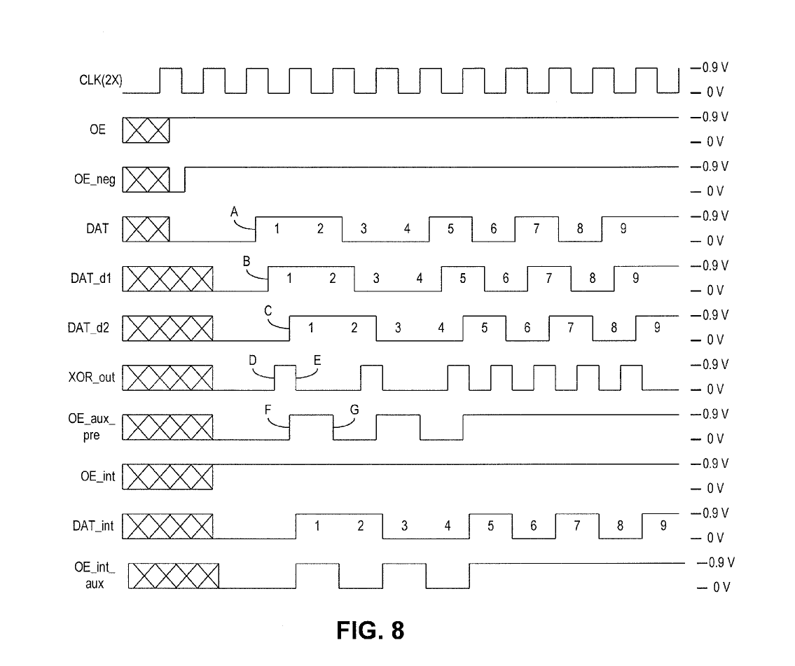

FIG. 7 shows a block diagram of an example configuration of circuit components of the dynamic impedance control circuit 502. Operation of the components of the dynamic impedance control circuit 502 is described with reference to FIG. 8, which shows a timing diagram of the signal received by and generated with the components of the dynamic impedance control circuit 502. The source signal DAT illustrated in FIGS. 6A and 6B is also illustrated in FIG. 8, with the same nine pulses of the source signal DAT being shown and labeled “1” through “9.” As previously described, the dynamic impedance control circuit 502 may be configured to receive the source signal DAT from the source circuit 102, and output the intermediate source signal DAT_int, which is a delayed version of the source signal DAT by about one clock cycle. Since the clock signal CLK is generated at twice the rate of the source signal DAT, then otherwise stated, the intermediate source signal DAT_int is a delayed version of the source signal DAT by one pulse-width duration of the source signal DAT or one period of the clock signal CLK. In addition, the dynamic impedance control circuit 502 may be configured to determine whether to generate the auxiliary intermediate enable signal OE_int_aux at either a high level or a low level for each of the pulses of the intermediate source signal DAT_int, and to make the determination within the one clock cycle delay by which the intermediate source signal DAT_int is generated.

In the example configuration shown in FIG. 7, the dynamic impedance control circuit 502 may be configured to generate the auxiliary intermediate enable signal OE_int_aux at its high level or low level based on a comparison of two consecutive pulses of the source signal DAT. In particular, the dynamic impedance control circuit 502 may include an XOR logic gate 702 that is configured to perform an XOR operation on the levels of two consecutive pulses for generation of the auxiliary intermediate enable signal OE_int_aux. The dynamic impedance control circuit 504 may further include a first tracking circuit 704 and a second tracking circuit 706 configured to generate delayed source signals used for the XOR operations.

As used herein, a tracking circuit may be configured to generate an output signal at levels that track (e.g., that matches and/or corresponds to) the levels of a received input signal at certain times determined by transitions of a received clock signal. A tracking circuit may be configured to generate its output signal at the level of the input signal on rising edges of the clock signal or on falling edges of the clock signal. The output signal that is output from a tracking circuit may be a delayed version of the input signal, delayed by an amount corresponding to the time a pulse of the input signal is received by the tracking circuit to the time that the next rising edge or falling edge of the clock signal occurs. FIG. 7 shows each of the tracking circuits receiving the clock signal CLK at a clock input “C.”

In addition, as described in further detail below, some of the tracking circuits may be configured to track the levels of the input signals on the rising edges of the clock signal CLK, while other tracking circuits may be configured to track the levels of the input signals on the falling edges of the clock signal CLK. For some example configurations, the clock signal CLK may be inverted before being sent to the clock input C of a tracking circuit configured to track on the falling edges. In other example configurations, inverter circuitry may be internal to a particular tracking circuit, or the tracking circuit may be otherwise internally configured, to track on the falling edges instead of the rising edges. Various ways of configuring the tracking circuits to track on the rising clock edges or the falling clock edges may be possible. For simplicity, in FIG. 7, those tracking circuits configured to track on the rising edges are shown as receiving the clock signal CLK at their respective clock inputs C, and those tracking circuits configured to track on the falling edges are shown as receiving an inverted clock signal CLKB at their respective clock inputs C. An example tracking circuit may be a flip flop, such as a D flip flop, although other circuit configurations for a tracking circuit may be possible.

In order for two consecutive pulses of the source signal DAT to be compared by the XOR logic gate 702 within a single clock cycle, the first and second tracking circuits 704, 706 may generate the delayed source signals based on consecutive edges or transitions of the clock signal. For a particular example configuration, the first delayed source signal DAT_d1 may be generated based on a falling edge of the clock signal CLK and the second delayed source signal DAT_d2 may be generated based on a next rising falling edge of the CLK. In further detail, the first tracking circuit 704 may be configured to receive at its input terminal “IN” the source signal DAT, and output the first delayed source signal DAT_d1 on the falling edges of the clock signal CIK. As shown in FIG. 7, the second tracking circuit 706 may be configured to receive at its input the first delayed source signal DAT_d1, and generate the second delayed source signal DAT_d2 on the rising edges of the clock signal CLK.

The first delayed source signal DAT_d1 may be supplied to a first input “IN1” of the XOR logic gate 702, and the second delayed source signal DAT_d2 may be supplied to a second input “IN2” of the XOR logic gate 702. By supplying the first delayed source signal DAT_d1 to the second tracking circuit 706, and configuring the second tracking circuit to track the levels of the first delayed source signal DAT_d1 on the rising clock edges, the second delayed source signal DAT_d2 is a delayed version of the first delayed source signal DAT_d1, delayed by an amount smaller than one clock cycle as determined by the consecutive falling and rising edges of the clock signal CLK.

As shown in FIG. 8, for a short period of time corresponding to the small amount of delay, corresponding pulses of the first delayed source signal DAT_d1 and the second delayed source signal DAT_d2 may not overlap. For example, due to the second delayed source signal DAT_d2 lagging the first delayed source signal DAT_d1, there may be a time period during which the XOR logic gate 702 receives corresponding first pulses for the first and second delayed source signals DAT_d1, DAT_d2, and then there may be a subsequent time period during which the XOR logic gate 702 is receiving the second pulse of the first delayed source signal DAT_d1 while still receiving the first pulse of the second delayed source signal DAT_d2. The same may occur for the second and third pulses, the third and fourth pulses, the fourth and fifth pulses, and so on. During this subsequent time period, the level of the output XOR_out of the XOR logic gate 702 is indicative of an XOR operation performed on two consecutive pulses.

Additionally, as shown in FIG. 7, the XOR output XOR_out may be provided to a third tracking circuit 708. In response, the third tracking circuit 708 may be configured to generate and output a pre-auxiliary intermediate enable signal OE_aux_pre on the rising edges of the clock signal CLK. The levels of the pre-auxiliary intermediate enable signal OE_aux_pre may indicate whether or not the auxiliary circuit 110 is to participate in the pull-up or push-down operations.

In addition, the dynamic impedance control circuit may include a fourth tracking circuit 710 that is configured to the enable signal OE from the source circuit 102. In response, the fourth tracking circuit 710 may be configured to generate an output signal OE_neg on the falling edges of the clock signal CLK. The output signal OE_neg of the fourth tracking circuit 710 may be supplied to an input of a fifth tracking circuit 712. In response, the fifth tracking circuit 712 may be configured to generate an output signal OE_int_pre on the rising edges of the clock signal CLK.

An example operation is described with reference to FIG. 8. As indicated by transition A, the first pulse of the source signal DAT may be generated at a high level. The first tracking circuit 704 may generate the first pulse of the first delayed source signal DAT_d1 on the next falling edge of the clock signal CLK, as indicated by transition B. The second tracking circuit 706 may generate the first pulse of the second delayed source signal DAT_d2 on the next rising edge of the clock signal CLK, as indicated by transition C. When the first delayed source signal DAT_d1 transitions to a high level, as indicated by transition B and before the second delayed source signal DAT_d2 transitions high, the XOR output XOR_out may be generated at a high level, as indicated by transition D. Then, when the second delayed source signal DAT_d2 transitions to a high level, the XOR output XOR_out may transition low, as indicated by transition E. After transition D occurs but before transition E occurs, the next rising edge of the clock signal CLK may occur, causing the third tracking circuit 708 to generate its output OE_aux_pre at a high level, as indicated by transition F. The output OE_aux_pre at the high level following transition F indicates that the auxiliary circuit 110 is to participate in the generation of the first pulse of the output signal DAT_OUT. The third tracking circuit 708 then tracks the XOR output XOR_out being at the low level following transition E, and transitions its output OE_aux_pre from high to low, as indicated by transition G. The transition to the low level as indicated by the transition G indicates that the auxiliary circuit is not to participate in the generation of the second pulse of the output signal DAT_OUT.

Referring back to FIG. 7, the dynamic impedance control circuit 502 may include buffer circuitry, including a first buffer circuit 714, a second buffer circuit 716, and a third buffer circuit 718 configured to output the intermediate source signal DAT_int, the primary intermediate enable signal OE_int, and the auxiliary intermediate enable signal OE_int_aux as time-aligned signals. As shown in FIG. 7, the second delayed source signal DAT_d2 may be the signal that is buffered by the first buffer circuit 714 to generate intermediate source signal DAT_int, the output OE_aux_pre of the third tracking circuit 708 may be buffered by the second buffer circuit 716 to generate the auxiliary intermediate enable signal OE_int_aux, and the output OE_int_pre of the fifth tracking circuit 712 may be buffered by the third buffer circuit 718 to generate the primary intermediate enable signal OE_int.

Also, for some example configurations, the dynamic impedance control circuit 502 may include an AND logic gate 720 positioned in between the first tracking circuit 704 and the second tracking circuit 706. The AND logic gate 720 may be configured to prevent the dynamic impedance control circuit 502 from outputting the intermediate source signal DAT_int and the auxiliary intermediate enable signal OE_int_aux at high levels when the source circuit 102 is indicating it does not want the output driver circuit 106 to generate the output signal DAT_OUT, such as by outputting the enable signal OE at a low level. As shown in FIG. 7, the fourth tracking circuit 710 may further be configured to supply its output OE_neg to an input of the AND logic gate 714. When the source circuit 102 outputs the enable signal OE at a high level, the fourth tracking circuit 710, in turn, generates its output OE_neg at a high level. With OE_neg at a high level, the AND logic gate 720 may pass the first delayed source signal DAT_d1 to the second tracking circuit 706. Conversely, when the enable signal OE is low, which in turn causes OE_neg to be low, the output of the AND logic gate 720 may be held to a low level, regardless of the level of the first delayed source signal DAT_d1.

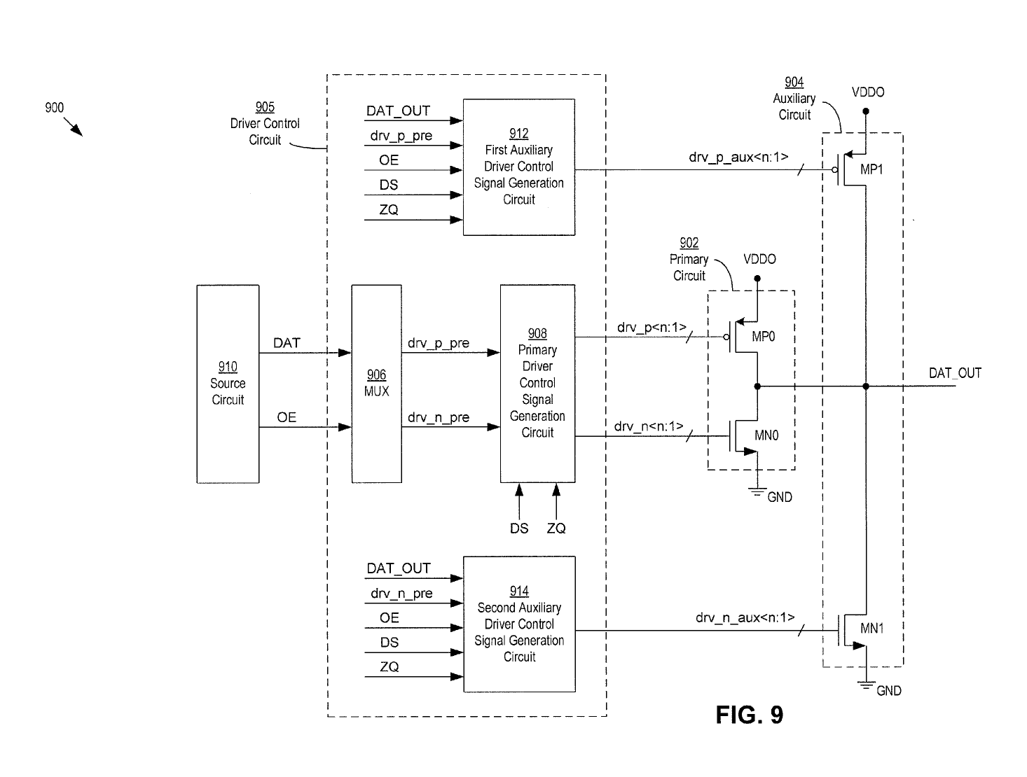

FIG. 9 shows a block diagram of another example circuit system 900 that may be configured to generate an output signal DAT_OUT. Similar to the example circuit system 100, the example circuit 900 may include an output driver circuit that includes a primary circuit 902 and an auxiliary circuit 904 to generate the output signal DAT_OUT. The primary circuit 902 may be configured the same as or similar to the primary circuit 108, and include a primary pull-up transistor MP0 and a primary push-down transistor MN0. Likewise, the auxiliary circuit 904 may be configured the same as or similar to the auxiliary circuit 110, and include an auxiliary pull-up transistor MP1 and an auxiliary push-down transistor MN1.

In addition, the primary circuit 902 and the auxiliary circuit 904 may be configured to operate in the same or similar way as the primary circuit 108 and the auxiliary circuit 110 of the example circuit system 100. That is, the primary circuit 902 may be constantly used to generate the output signal DAT_OUT, and the auxiliary circuit 904 may be selectively, variably, or only sometimes used to generate the output data signal DAT_OUT. That is, for two consecutive pulses of the output signal DAT_OUT, including a current pulse and an immediately preceding or prior pulse, the auxiliary circuit 110 may contribute to or participate in the generation of a current pulse in response to the voltage level of the current pulse being different than the voltage level of the immediately preceding pulse, in response to the voltage level of the current pulse and the voltage level of the immediately preceding pulse corresponding to different logic levels, and/or in response to the primary circuit 902 generating the voltage of the output signal DAT_OUT to cross an associated threshold level during generation of the consecutive pulses.

The example circuit system 900 may further include a driver control circuit 905 that is configured to generate primary pull-up and push-down control signals drv_p<n:1>, drv_n<n:1> to control operation of the primary circuit 902 and auxiliary pull-up and push-down control signals drv_p_aux<n:1>, drv_n_aux<n:1> to control operation of the auxiliary circuit 904. The driver control circuit 905 may include a multiplexer (MUX) 906 and a primary driver control signal generation circuit 908 to control operation of the primary circuit 902.

The multiplexer 906 and the primary driver control signal generation circuit 908 may be configured the same as or similar to the first multiplexer 504 and the driver control signal generation circuit 508 for control of the primary circuit 108. As shown in FIG. 9, the primary driver control signal generation circuit 908 may be configured to generate and output one or more primary pull-up control signals drv_p<n:1> to control operation of the primary pull-up transistor MP0 and one or more primary push-down control signals drv_n<n:1> to control operation of the primary push-down transistor MN0. The levels at which the primary driver control signal generation circuit 908 generates at least one of the primary pull-up control signals drv_p<n:1>, represented by and/or referred to as an ith primary pull-up control signal drv_p(i), may be responsive to the levels of a pull-up pre-control signal drv_p_pre received from the multiplexer 906. The other primary pull-up control signals drv_p<n:1> not responsive to the pull-up pre-control signal drv_p_pre may be responsive to and/or determined by the driver strength and impedance control signals DS, ZQ, as is the case with primary pull-up control signals drv_p<n:1> output by the driver control signal generation circuit 508 of FIG. 5. Similarly, the levels at which the primary driver control signal generation circuit 908 generates at least one of the primary push-down control signals drv_n<n:1>, represented by and/or referred to as an ith primary push-down control signal drv_n(i), may be responsive to the levels of a push-down pre-control signal drv_n_pre received from the multiplexer 906. The other primary push-down control signals drv_n<n:1> not responsive to the push-down pre-control signal drv_n_pre may be responsive to and/or determined by the driver strength and impedance control signals DS, ZQ, as is the case with primary push-down control signals drv_n<n:1> output by the driver control signal generation circuit 508 of FIG. 5.

In addition, similar to the driver control signal generation circuit 508 of FIG. 5, for at least some example configurations, the primary driver control signal generation circuit 908 may be configured to generate the ith primary pull-up control signal drv_p(i) and the ith primary push-down control signal drv_n(i) at voltage levels that inversely track the voltage levels of the pull-up pre-control signal drv_p_pre and the push-down pre-control signal drv_n_pre, respectively.

Also, similar to the source circuit 102, the example circuit system 900 of FIG. 9 may include a source circuit 910 configured to generate and output a source signal DAT and an enable signal OE. As previously described with respect to the example system 100, the primary circuit 902 may be configured to generate the pulses of the output signal DAT_OUT at voltage levels corresponding to the voltage levels of the source signal DAT. For example configurations where there is a direct relationship between the source signal DAT and the output signal DAT_OUT, for a given pulse of the source signal DAT output at a high voltage level, the primary circuit 902 may perform a pull-up operation to generate a corresponding pulse of the output signal DAT_OUT at an associated high voltage level. Accordingly, when the source circuit 910 outputs a given pulse of the source signal DAT at a high voltage level (and assuming the enable signal OE is at an activation (e.g., high) level), the multiplexer 906 may respond by outputting the pull-up pre-control signal drv_p_pre and the push-down pre-control signal drv_n_pre each at an associated high level, which in turn may cause the primary driver control signal generation circuit 908 to output the ith primary pull-up control signal drv_p(i) and the ith primary push-down control signal drv_n(i) each at an associated low level in order to cause the primary circuit 902 to perform a pull-up operation to generate the corresponding pulse. In a similar manner, for a given pulse of the source signal DAT output at a low voltage level, the primary circuit 902 may perform a push-down operation to generate a corresponding pulse of the output signal DAT_OUT at an associated low voltage level. Accordingly, when the source circuit 910 outputs a given pulse of the source signal DAT at a low voltage level (and assuming the enable signal OE is at an activation (e.g., high) level), the multiplexer 906 may respond by outputting the pull-up pre-control signal drv_p_pre and the push-down pre-control signal drv_n_pre each at an associated low level, which in turn may cause the primary driver control signal generation circuit 908 to output the ith primary pull-up control signal drv_p(i) and the ith primary push-down control signal drv_n(i) each at an associated high level in order to cause the primary circuit 902 to perform a push-down operation to generate the corresponding pulse.

One difference between the example circuit system 100 and the example circuit system 900 is the consecutive pulses that are used for control of the auxiliary circuit. As previously described with respect to FIG. 5 and FIG. 7, the circuit system 100 includes a dynamic impedance control circuit 502 that delays the source signal DAT a certain number of times such that two pulses corresponding to two consecutive pulses of the source signal DAT are compared, such as through use of the XOR logic gate 702 (FIG. 7). The dynamic impedance control circuit 502 may generate the delayed signals using the rising and falling edges of a clock signal CLK output from the source signal 102, as previously described. In contrast, the circuit system 900 may utilize a feedback network that feeds back the output signal DAT_OUT to be used for a comparison of consecutive pulses to control the auxiliary circuit 904. Clocking may not be needed to implement the feedback and generate control signals to generate the primary and auxiliary control signals drv_p<n:1>, drv_n<n:1>, drv_p_aux<n:1>, drv_n_aux<n:1>. Accordingly, as shown in FIG. 9, a clock signal CLK is not output from the source circuit 910 to the driver control circuit 905, in contrast to the circuit system 100, where the source circuit 102 outputs a clock signal CLK to the driver control circuit 104.

In further detail, instead of using the dynamic impedance control circuit 502 to compare consecutive pulses, the circuit system 900 may include a first auxiliary driver control signal generation circuit 912 and a second auxiliary driver control signal generation circuit 914. For pairs of consecutive pulses that each include a current pulse and a next pulse, the current pulses may be the pulses of the output signal DAT_OUT and the next pulses may be the pulses of the pull-up pre-control signal drv_p_pre or the pulses of the push-down pro-control signal drv_n_pre.

As shown in FIG. 9, the first auxiliary driver control signal generation circuit 912 may be configured to output one or more auxiliary pull-up control signals drv_p_aux<n:1> to control operation of the auxiliary pull-up transistor MP1. In addition, the first auxiliary driver control signal generation circuit 912 may be configured to receive the pull-up pre-control signal drv_p_pre and the output signal DAT_OUT. The first auxiliary driver control signal generation circuit 912 may further be configured to compare the levels of the pull-up pre-control signal drv_p_pre and the levels of the output signal DAT_OUT. The first auxiliary driver control signal generation circuit 912 may be configured to output at least one of the auxiliary pull-up control signals drv_p_aux<n:1>, referred to as an ith auxiliary pull-up control signal drv_p_aux(i), at a level responsive to the comparison. The other auxiliary pull-up control signals drv_p_aux<n:1> not responsive to the comparison may be responsive to and/or determined by the driver strength and impedance control signals DS, ZQ, as is the case with auxiliary pull-up control signals drv_p_aux<n:1> output by the driver control signal generation circuit 508 of FIG. 5.

In particular, at a given point in time or within a given comparison window, one of four possible situations may occur with respect to the voltage levels of the output signal DAT_OUT and the pull-up pre-control signal drv_p_pre: (1) the output signal DAT_OUT and the pull-up pre-control signal drv_p_pre are both at high levels; (2) the output signal DAT_OUT is at a high level and the pull-up pre-control signal drv_p_pre is at a low level; (3) the output signal DAT_OUT is at a low level and the pull-up pre-control signal drv_p_pre is at a high level; or (4) the output signal DAT_OUT and the pull-up pre-control signal drv_p_pre are both at low levels.

In the first situation, the output signal DAT_OUT and the pull-up pre-control signal drv_p_pre both at high levels may indicate that the primary circuit 902 is to generate the next pulse of the output signal DAT_OUT at the same, high voltage level as the current pulse and so the auxiliary circuit 904 is to be deactivated during generation of the next pulse. Accordingly, the first auxiliary driver control signal generation circuit 912 may generate the ith auxiliary pull-up control signal drv_p_aux(i) at a high level so that a corresponding ith auxiliary pull-up transistor MP1(i) is turned off during generation of the next pulse.

In the second situation, the output signal DAT_OUT at a high level and the pull-up pre-control signal drv_p_pre at a low level may indicate that the primary circuit 902 is to generate the next pulse of the output signal DAT_OUT at a low level, which is different than the high level at which the current pulse is generated, and so the voltage of the output signal DAT_OUT will cross an associated threshold level during generation of the current and next pulses, and the auxiliary circuit 904 is to be activated and perform a push-down operation to contribute to the generation of the next pulse at the low level. Accordingly, the first auxiliary driver control signal generation circuit 912 may generate the ith auxiliary pull-up control signal drv_p_aux(i) at a high level so that the corresponding ith auxiliary pull-up transistor MP1(i) is turned off during generation of the next pulse.

In the third situation, the output signal DAT_OUT at a low level and the pull-up pre-control signal drv_p_pre at a high level may indicate that the primary circuit 902 is to generate the next pulse of the output signal DAT_OUT at a high level, which is different than the low level at which the current pulse is generated, and so the voltage of the output signal DAT_OUT will cross an associated threshold level during generation of the current and next pulses, and the auxiliary circuit 904 is to be activated and perform a pull-up operation to contribute to the generation of the next pulse at the high level. Accordingly, the first auxiliary driver control signal generation circuit 912 may generate the ith auxiliary pull-up control signal drv_p_aux(i) at a low level so that the corresponding ith auxiliary pull-up transistor MP1(i) is turned on to during generation of the next pulse.

In the fourth situation, the output signal DAT_OUT and the pull-up pre-control signal drv_p_pre both at low levels may indicate that the primary circuit 902 is to generate the next pulse of the output signal DAT_OUT at the same, low voltage level as the current pulse and so the auxiliary circuit 904 is to be deactivated during generation of the next pulse. Accordingly, the first auxiliary driver control signal generation circuit 912 may generate the ith auxiliary pull-up control signal drv_p_aux(i) at a high level so that the corresponding ith auxiliary pull-up transistor MP1(i) is turned off during generation of the next pulse.

As shown in FIG. 9, the second auxiliary driver control signal generation circuit 914 may be configured to output one or more auxiliary push-down control signals drv_n_aux<n:1> to control operation of the auxiliary push-down transistor MN1. In addition, the second auxiliary driver control signal generation circuit 914 may be configured to receive the push-down pre-control signal drv_n_pre and the output signal DAT_OUT. The second auxiliary driver control signal generation circuit 912 may further be configured to compare the levels of the push-down pre-control signal drv_n_pre and the levels of the output signal DAT_OUT. The second auxiliary driver control signal generation circuit 914 may be configured to output at least one of the auxiliary push-down control signals drv_n_aux<n:1>, referred to as an ith auxiliary push-down control signal drv_n_aux(i), at a level responsive to the comparison. The other auxiliary push-down control signals drv_n_aux<n:1> not responsive to the comparison may be responsive to and/or determined by the driver strength and impedance control signals DS, ZQ, as is the case with auxiliary push-down control signals drv_n_aux<n:1> output by the driver control signal generation circuit 508 of FIG. 5.

Similar to the four situations previously described with respect first auxiliary driver control signal generation circuit 912, at a given point in time or within a given comparison window, one of four possible situations may occur with respect to the voltage levels of the output signal DAT_OUT and the push-down pre-control signal drv_n_pre: (1) the output signal DAT_OUT and the push-down pre-control signal drv_n_pre are both at high levels; (2) the output signal DAT_OUT is at a high level and the push-down pre-control signal drv_n_pre is at a low level; (3) the output signal DAT_OUT is at a low level and the push-down pre-control signal drv_n_pre is at a high level; or (4) the output signal DAT_OUT and the push-down pre-control signal drv_n_pre are both at low levels.

In the first situation, the output signal DAT_OUT and the push-down pre-control signal drv_n_pre both at high levels may indicate that the primary circuit 902 is to generate the next pulse of the output signal DAT_OUT at the same, high voltage level as the current pulse and so the auxiliary circuit 904 is to be deactivated during generation of the next pulse. Accordingly, the second auxiliary driver control signal generation circuit 914 may generate the ith auxiliary push-down control signal drv_n_aux(i) at a low level so that a corresponding ith auxiliary push-down transistor MN1(i) is turned off during generation of the next pulse.

In the second situation, the output signal DAT_OUT at a high level and the push-down pre-control signal drv_n_pre at a low level may indicate that the primary circuit 902 is to generate the next pulse of the output signal DAT_OUT at a low level, which is different than the high level at which the current pulse is generated, and so the voltage of the output signal DAT_OUT will cross an associated threshold level during generation of the current and next pulses, and the auxiliary circuit 904 is to be activated and perform a push-down operation to contribute to the generation of the next pulse at the low level. Accordingly, the second auxiliary driver control signal generation circuit 914 may generate the ith auxiliary push-down control signal drv_n_aux(i) at a high level so that the corresponding ith auxiliary push-down transistor MN1(i) is turned on during generation of the next pulse.

In the third situation, the output signal DAT_OUT at a low level and the push-down pre-control signal drv_n_pre at a high level may indicate that the primary circuit 902 is to generate the next pulse of the output signal DAT_OUT at a high level, which is different than the low level at which the current pulse is generated, and so the voltage of the output signal DAT_OUT will cross an associated threshold level during generation of the current and next pulses, and the auxiliary circuit 904 is to be activated and perform a pull-up operation to contribute to the generation of the next pulse at the high level. Accordingly, the second auxiliary driver control signal generation circuit 914 may generate the ith auxiliary push-down control signal drv_n_aux(i) at a low level so that the corresponding ith auxiliary push-down transistor MN1(i) is turned off during generation of the next pulse.

In the fourth situation, the output signal DAT_OUT and the push-down pre-control signal drv_n_pre both at low levels may indicate that the primary circuit 902 is to generate the next pulse of the output signal DAT_OUT at the same, low voltage level as the current pulse and so the auxiliary circuit 904 is to be deactivated during generation of the next pulse. Accordingly, the second auxiliary driver control signal generation circuit 914 may generate the ith auxiliary push-down control signal drv_n_aux(i) at a low level so that the corresponding ith auxiliary push-down transistor MN1(i) is turned off during generation of the next pulse.

Each of the first auxiliary driver control signal generation circuit 912 and the second auxiliary driver control signal generation circuit 914 may be configured in various ways. In one example configuration, the first auxiliary driver control signal generation circuit 912 and the second auxiliary driver control signal generation circuit 914 may be configured as glitch detection circuits. In one example configuration, the glitch detection circuit may include a delay chain that converges and a NAND logic circuit block that generates a glitch. For another example configuration, the glitch detection circuit may generate the glitch through the comparisons of the output signal DAT_OUT and the pull-up or push-down pre-control signals drv_p_pre, drv_n_pre.

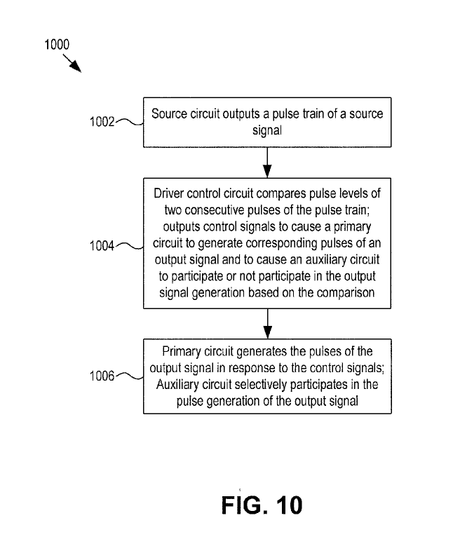

FIG. 10 is a flow chart of an example method 1000 of generating an output signal. At block 1002, a source circuit, such as the source circuit 102 or the source circuit 910 as previously described with reference to FIGS. 1-9, may generate a source signal that includes a pulse train of pulses generated at high and low levels. The source circuit may output the source signal to a driver control circuit, such as the driver control circuit 104 or the driver control circuit 905 as previously described with reference to FIGS. 1-9.

At block 1004, the driver control circuit may detect levels of the pulses of the source signal and compare levels of pulses corresponding to consecutive pulses of the source signal. For some example methods, the pulses that are compared are generated from two delayed versions of the source signal, such as described with reference to FIGS. 7 and 8. For other example methods, the pulses that are compared include pulses of a pre-control signal indicating levels of next pulses of the output signal and pulses of the output signal indicating levels of current pulses, as described with reference to FIG. 9.

In response to the detection and comparison, the driver control circuit may generate control signals to control operation of a primary circuit and an auxiliary circuit of an output driver circuit, such as the primary circuit 108 or the primary circuit 902 and the auxiliary circuit 110 or the auxiliary circuit 904 as previously described with reference to FIGS. 1-9. The output driver circuit may generate corresponding pulses of an output signal that correspond to the pulses of the source signal. For some example methods, if a given pulse of the source signal is at a high level, the control signals may be generated to cause the primary circuit to generate a corresponding pulse of the output signal at a high level, such as by causing the primary circuit to perform a pull up operation. Similarly, if a given pulse of the source signal is at a low level, the control signals may be generated to cause the primary circuit to generate a corresponding pulse of the output signal at a low level.

Also, based on the comparison of consecutive pulses, the driver circuit may be configured to generate control signals to cause the auxiliary circuit to participate or not participate in the generation of the pulses of the output signal. For example, as previously described, if generation of two consecutive pulses of the output signal includes a threshold level being crossed and/or generating the pulses to correspond to different logic levels, the driver control circuit may output the control signals to cause the auxiliary circuit to participate in the generation of the latter of the two consecutive pulses. If the latter pulse is to be generated above the threshold level and/or at a level to correspond to a logic 1 value, then the driver control circuit may generate the control signal to cause the auxiliary circuit to perform a pull up operation. Alternatively, if the latter pulse is to be generated below the threshold level and/or at a level to correspond to a logic 0 value, then the driver control circuit may generate the control signal to cause the auxiliary circuit to perform a push down operation. Alternatively, if generation of two consecutive pulses of the output signal does not include a threshold level being crossed and/or the two consecutive pulses are generated to correspond to the same logic levels, then the driver control circuit 104 may generate the control signals so that the auxiliary circuit is deactivated—e.g., so that the auxiliary circuit does not perform either a pull-up operation or a push-down operation.

At block 1006, the primary and secondary circuit of the output driver circuit may generate the pulses of the output signal in response to the control signals received from the driver control circuit. Depending on the levels of the control signals, the primary circuit may perform pull-up or push-down operations to generate each of the pulses of the output signal. In addition, depending on the levels of the control signals, the auxiliary circuit may selectively or sometimes participate in generating the pulses. If the auxiliary circuit participates, then the auxiliary circuit may perform the same pull-up or push-down operation as the primary circuit for generation of a particular pulse. Alternatively, if the auxiliary circuit does not participate, then both the pull-up and push-down components of the auxiliary circuits are deactivated or turned off so that the auxiliary circuit is uninvolved in the generation of a particular pulse.

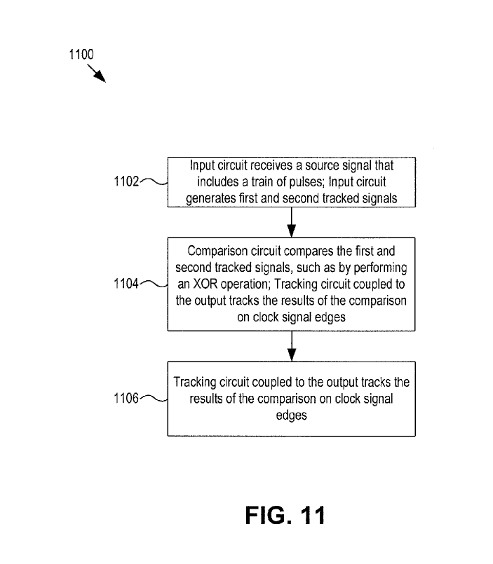

FIG. 11 is a flow chart of an example method 1100 of generating a control signal used to cause an auxiliary circuit to selectively participate in generating an output signal. The example method 1100 may be performed with a circuit, such as one that includes one or more circuit components of the dynamic impedance control circuit 502 of FIG. 5. At block 1102, an input circuit, such as a circuit including the first tracking circuit 704 and the second tracking circuit 706, may be receive a source signal from a source circuit. The source signal may include a pulse train of pulses. In response to the source signal, the input circuit may generate a first tracked or delayed source signal and a second tracked or delayed source signal. In some example methods, the first tracked source signal may be generated by tracking the levels of the source signal on the falling edges of a clock signal, and the second tracked source signal may be generated by tracking the levels of the first tracked source signal on the rising edges of the clock signal. Also, in some example methods, the input circuit may receive the clock signal from the source circuit. In addition or alternatively, the clock signal may be twice the rate as the source signal. That is, one pulse of the source signal may extend over and/or correspond to a full cycle of the clock signal.

At block 1104, a comparison circuit, such as a circuit including the XOR logic gate 702 and the third tracking circuit 708 coupled to the output of the XOR logic gate 702 of FIG. 7, may compare the first tracked source signal and the second tracked source signal, and generate an output based on the comparison. In some example methods, the comparison operation may include an XOR operation. At block 1106, a tracking circuit may track the results of the comparison, such as the results of the XOR operation, on edges or transitions of the clock signal. In some example methods, the tracking circuit may track the results on the rising edges of the clock signal. The output of the tracking circuit may be control signal. In other example methods, the output of the tracking signal may be buffered, and the buffered version of the output of the tracking circuit may be the control signal output by the circuit performing the example method 1100. Also, in some example methods, the second tracked source signal, or a buffered version of the second tracked source signal, may used as an intermediate source signal by a downstream circuit, such as the second multiplexer 508 of FIG. 5, in combination with the control signal, to generate further control signals for controlling whether the auxiliary circuit 110 participates in a pull-up operation, participates in a push-down operation, or does not participate in either a pull-up or push-down operation.

Other or additional methods may be performed, including those that include more or fewer actions than those described with reference to FIGS. 10 and 11. For example, some example methods may include a combination of actions performed in the example methods 1000 and 1100. Other example methods may include certain actions performed by the circuit components described with reference to FIGS. 1-9.

The above-described circuits and related methods can be implemented in and/or applicable for any systems, apparatuses, devices, or circuits that generate an output signal based on an input signal, especially those where it is desirable for an output circuit to have a variable impedance when generating the output signal. One example application is non-volatile memory systems in which a controller communicates with one or more non-volatile memory dies. In one particular example configuration with reference to FIGS. 1 and/or 9, the source circuit 102 and/or 910 may be a core logic circuit of the controller, and the source signal DAT may be a data signal containing data that is to be stored in the non-volatile memory. The data is contained in the data signal DAT in the form of a series of voltage pulses, with the level of each pulse corresponding to a logic value of an associated bit or multi-bit logic value of associated plurality of bits. The primary circuit 108 or 902 and the auxiliary circuit 110 or 904 of the output driver circuitry may be configured to generate an output data signal DAT_OUT corresponding to the data signal DAT output by the core logic circuit 102 or 910. The output node OUT on which the output data signal DAT_OUT is generated may be and/or may be coupled to a conductive output pad (e.g., a bond pad), which in turn is coupled to a corresponding pad on the memory die receiving the output data signal DAT_OUT.

For some non-volatile memory applications, especially for those that include multiple memory dies, the output node OUT may be coupled in parallel to several pads located on different memory dies. As a general rule, the more bond pads that the output node OUT is coupled to in parallel, the larger the output capacitance. As more memory dies are added to a non-volatile memory device to increase storage capacity, the larger the drive strength the output driver circuit needs in order to overcome the increased output capacitance and meet the swing requirement of the output data signal DAT_OUT. Conversely, if the output driver circuit does not have enough drive strength to generate the output data signal, it may generate the output data signal with too small of voltage swings (i.e., the output data signal DAT_OUT is not sufficiently meeting the swing requirements), which in turn may lead to loss in signal integrity and an increased amount of errors when reading the data from the non-volatile memory.

At the same time, it may be desirable to increase the rate or throughput at which the output data signal DAT_OUT is being communicated, such as by increasing the Toggle Mode (TM) rate and/or utilizing double-data rate (DDR) schemes. As previously described, high frequency components may be attenuated more than the low frequency components of a signal. As such, increasing the rate may result in increased attenuation of the high frequency components of the output data signal DAT_OUT.

As previously described, when the auxiliary circuit 110 or 904 contributes to or participates in the generation of a pulse with the primary circuit 108 or 902, the overall impedance of the output driver circuit decreases, which in turn increases the drive strength that the output driver circuit has to generate the pulse. Doing so may help in compensating the losses in high frequency components and meet the challenge of keeping signal integrity high despite increased numbers of memory dies and/or increased data rates.

In some example configurations, the output driver circuit 106 may be configured to generate the output signal DAT_OUT according to a swing requirement, which may specify a high voltage level V_{OH} and a low voltage level V_{OL}, with the high voltage level V_{OH} being higher than the low voltage level V_{OL}. The high voltage level V_{OH} may be a level below a highest voltage level at which the pulses may be generated, such as the supply voltage level VDDO, and the low voltage level V_{OL} may be a level above the lowest voltage level at which the pulses may be generated, such as the ground reference voltage level GND. In this regard, a voltage transition between the high voltage level V_{OH} and the low voltage level V_{OL} may be smaller in magnitude compared to a rail-to-rail transition extending from the supply voltage level VDDO to ground GND.

Pulses generated at or above the high voltage level V_{OH} may programmed as, read as, or otherwise correspond to bits having a logic 1 level or value, and pulses generated at or above the low voltage level V_{OL} may be programmed as, read as, or otherwise correspond to bits having a logic 0 level or value. In this sense, the high voltage level V_{OH} and the low threshold level V_{OL} may be considered a pair of threshold levels. The output driver circuit 106 may be configured to meet the swing requirement by generating pulses of the output signal DAT_OUT that correspond to logic 1 levels at or above the high threshold level V_{OH} and by generating pulses of the output signal DAT_OUT that correspond to logic 0 levels at or below the low threshold level V_{OL}.

In addition, the output driver circuit 106, including the primary circuit 108 and the auxiliary circuit 110, may be configured in conjunction with on-die termination (ODT) resistance of the memory dies. ODT resistance circuits may be coupled to transmission lines over which the data signal DAT_OUT is communicated between the controller and the memory dies. For example, an ODT resistance circuit may be coupled to a bond pad on a memory die. ODT circuits may be included to improve signal integrity, such as by reducing reflections and energy loss, particularly for generally high speed operation. However, coupling ODT resistance circuits to the transmission lines may also have the effect of reducing or limiting the voltage swing of the output signal DAT_OUT, such as by causing the voltage swing to be smaller than rail-to-rail. As indicated in equations (1) and (2) below, the impedances of the primary circuit 108 and the auxiliary circuit 110 may be set to and/or optimized for the ODT resistance.

As described above, the output driver circuit 106 may generate two consecutive pulses at the same voltage level or at different voltage levels. In the context of the high and low voltage levels V_{OH}, V_{OL} and the ability of the output driver circuit 106 to meet the swing requirement, the output driver circuit 106 may generate two consecutive pulses both at or above the high voltage level V_{OH}, both at or below the low voltage level V_{OL}, or one at or above the high voltage level V_{OH} and the other pulse at or above the low voltage level V_{OL}. The situations where the two consecutive pulses are generated both at or above the high voltage level V_{OH} or both at or below the low voltage level V_{OL} may be considered a low frequency situation since the voltage level of the output signal DAT_OUT is not changing or changing relatively little over the time duration of the two pulses. The other situation where one pulse is generated at or above the high voltage level V_{OH} and the other is generated at or below the low voltage level V_{OL} may be considered a high frequency situation since the change in voltage level is at least the voltage swing between the high voltage level V_{OH} and the low voltage level V_{OL} over the time duration of the two pulses. In this context, the low frequency situation may correspond to the voltage swing between the high voltage level V_{OH} and the low voltage level V_{OL} not occurring or not being achieved during generation of the two pulses, and the high frequency situation may correspond to the voltage swing between the high voltage level V_{OH} and the low voltage level V_{OL} occurring or being achieved during generation of the two pulses.

In terms of the high voltage level V_{OH} and the low voltage level V_{OL} being thresholds, the high frequency situation may correspond to a change in the voltage level of the output signal DAT_OUT exceeding a threshold amount of voltage during generation of the two consecutive pulses, and the low frequency situation may correspond to the voltage level not exceeding the threshold amount of voltage during generation of the two consecutive pulses. The auxiliary circuit 110 may participate in or contribute to the generation of the second of the two consecutive pulses in response to the change in voltage exceeding the threshold amount of voltage during generation of the two pulses, and may not participate in or contribute to the generation of the second pulse in response to the change of voltage not exceeding the threshold amount of voltage during generation of the two pulses.

The output driver circuit 106 may be configured to generate two consecutive pulses with a first optimal impedance R_{eq1} for the low frequency situation, and a second optimal impedance R_{eq2} for the high frequency situation. Mathematically, the first and second optimal impedances R_{eq1}, R_{eq2} may be represented by the following mathematical equations:

$$\begin{matrix}{R}_{eq 1} = \frac{2 {V}_{OL}}{( VDDO - 2 {V}_{OL} )} \times {R}_{tt} & ( 1 ) \\ {T}_{bit} = \frac{( {R}_{eq 2} \times {R}_{tt} )}{( {R}_{eq 2} + {R}_{tt}} \cdot {C}_{L} \cdot ln [ \frac{\frac{2 {V}_{OH}}{VDDO} - \frac{{R}_{eq 2}}{( {R}_{eq 2} + {R}_{tt} )}}{\frac{2 {V}_{OL}}{VDDO} - \frac{{R}_{eq 2}}{( {R}_{eq 2} + {R}_{tt} )}} ] & ( 2 )\end{matrix}$$

where Rₜₜ is the on-die termination resistance, T_{bit} is the pulse duration or time period of a pulse of the output signal DAT_OUT, and C_{L} is the load capacitance of the memory dies.

Where the first optimal impedance R_{eq1} and the second optimal impedance R_{eq2} are different, the output driver circuit 106 may be configured to optimally generate the output signal DAT_OUT by being configured to generate the output signal DAT_OUT with a variable impedance for the various high frequency and low frequency situations occurring over multiple consecutive pulses. That is, the output driver circuit 106 may be configured to generate the second pulse of the two consecutive pulses with the first impedance R_{eq1} for the low frequency situations, and may be configured to generate the second pulse with the second impedance R_{eq2} for the high frequency situations.

To do so, as explained above, the output driver circuit 106 may be configured to include or be “split” into the primary circuit 108 and the auxiliary circuit 110. The first optimal impedance R_{eq1} may be the impedance of the primary circuit 108, and the second optimal impedance R_{eq2} may the combined parallel impedance of the primary circuit 108 and the auxiliary circuit 110. By configuring the primary circuit 108 and the auxiliary circuit 110 so that the impedance of the primary circuit 108 is the first optimal impedance R_{eq1} and the parallel combination of the primary circuit 108 and the auxiliary circuit 110 is the second optimal impedance R_{eq2}, the primary circuit 108 may operate and/or be configured with an impedance to ensure that the voltage swing between the high voltage level V_{OH} and the low voltage level V_{OL} is met during generation of the pulses of the output signal DAT_OUT, and the second circuit 110 may operate and/or be configured to ensure that the voltage transitions satisfy the timing requirements determined by the data rate or frequency requirements of the output signal DAT_OUT, as indicated by the pulse duration T_{bit}. Otherwise stated, the primary circuit 108 and the auxiliary circuit 110 may operate in tandem and be configured with appropriate impedances so that the overall drive impedance of the output driver circuit 106 is emphasized for the high frequency situations, and so that logic level retention is achieved during the low frequency situations.

With particular reference to equation (2), since the second optimal impedance R_{eq2} may be determined based on the pulse duration of the output signal DAT_OUT, the primary circuit 108 and the auxiliary circuit 110 may be configured to optimally generate the output signal DAT_OUT for any of various frequencies or data rates, and thus may be an optimal configuration for the output driver circuitry of memory or other electronic systems that desire or require communication at high frequencies or data rates, such as in the Gigahertz (GHz) range or in a Giga-bit Toggle Mode (TM), or above. Similarly, since the second optimal impedance R_{eq2} may be determined based on the die load capacitance C_{L}, the primary circuit 108 and the auxiliary circuit 110 may be configured to optimally generate the output signal DAT_OUT for any of various numbers of memory dies, and thus may be an optimal configuration for the output driver circuitry of memory or other electronic system that desire or require an increased number of memory dies.

As far as performance, the primary circuit 108 and the auxiliary circuit 110 may be configured to optimally generate the output signal DAT_OUT in terms of minimized inter-symbol interference (ISI), data dependent jitter (DDJ), duty-cycle distortion, and supply noise, and an improved data valid window (as indicated by an eye pattern or eye diagram)—over the various high frequency and low frequency situations occurring for consecutive pulses of the output signal DAT_OUT. Overall power efficiency and size of the I/O circuitry may also be optimized or enhanced as a result of configuring the output driver circuit 106 into its primary and auxiliary components. In sum, the primary and auxiliary circuit configuration of the output driver circuit 106 and its associated control circuitry may provide a “real-time dynamic data aware” impedance control approach in which the impedance of the output driver circuit 106 is dynamically varied in real time based on the voltage levels of the data signal, and the logic levels to which the voltage levels correspond, to optimally generate the data signal. Since the impedance is varied in real-time, the circuit systems do not require any special training, especially as data rates move to higher speeds.

It is intended that the foregoing detailed description be understood as an illustration of selected forms that the invention can take and not as a definition of the invention. It is only the following claims, including all equivalents, that are intended to define the scope of the claimed invention. Finally, it should be noted that any aspect of any of the preferred embodiments described herein can be used alone or in combination with one another.

1. A circuit comprising:
a driver control circuit configured to output a driver control signal to:
activate a first push-pull circuit to generate an output data signal;
activate a second push-pull circuit to contribute to generation of a subsequent pulse of a pair of consecutive pulses of the output data signal when a voltage of the output data signal crosses a threshold level to generate the subsequent pulse; and
deactivate the second push-pull circuit from contributing to generation of the subsequent pulse of the pair of consecutive pulses when the voltage does not cross the threshold level to generate the subsequent pulse; and
a voltage mode output driver circuit comprising the first push-pull circuit and the second push-pull circuit, the voltage mode output driver circuit configured to:
generate the output data signal with a first overall impedance in response to the driver control signal activating both the first push-pull circuit and the second push-pull circuit; and
generate the output data signal with a second overall impedance in response to the driver control signal activating the first push-pull circuit and deactivating the second push-pull circuit.

2. The circuit of claim 1, wherein the second push-pull circuit is configured to contribute to generation of the subsequent pulse of the output data signal when the first push-pull circuit generates the voltage to cross the threshold level during generation of the subsequent pulse and an immediately preceding pulse of the pair of consecutive pulses.

3. The circuit of claim 1, wherein the second push-pull circuit is configured to not contribute to generation of the subsequent pulse when the first push-pull circuit generates the voltage not to cross the threshold level during generation of the subsequent pulse and an immediately preceding pulse of the pair of consecutive pulses.

4. (canceled)

5. The circuit of claim 1, wherein the driver control circuit comprises a dynamic impedance control circuit configured to:
receive the input signal; and
perform an XOR operation on pulses of the input signal corresponding to the subsequent pulse and an immediately preceding pulse of the pair of consecutive pulses of the output data signal.

6. The circuit of claim 5, wherein the dynamic impedance control circuit is further configured to:
receive a clock signal oscillating at a rate that is twice a rate of the output data signal; and
perform the XOR operation according to transitions of the clock signal.

7. The circuit of claim 5, wherein the dynamic impedance control circuit further comprises:
a first tracking circuit configured to:
track the input signal on one of rising edges or falling edges of the clock signal to generate a first tracked signal; and
output the first tracked signal to a first input of an XOR logic circuit for performance of the XOR operation; and
a second tracking circuit configured to:
track the first tracked signal on the other of the rising edges or the falling edges of the clock signal to generate a second tracked signal; and
output the second tracked signal to a second input of the XOR logic circuit for performance of the XOR operation.

8. (canceled)

9. A circuit comprising:
a voltage mode driver circuit configured to generate an output signal carrying data with a variable impedance, the voltage mode driver circuit comprising a first push-pull circuit and a second push-pull circuit; and
a driver control circuit configured to:
output a control signal to activate both the first push-pull circuit and the second push-pull circuit in order to generate a current pulse of the output signal with the variable impedance at a first impedance value in response to the current pulse having a different logic level than an immediately preceding pulse of the output signal; and
output the control signal to activate the first push-pull circuit and deactivate the second push-pull circuit in order to generate the current pulse with the variable impedance at a second impedance value in response to the current pulse having the same logic level as the immediately prior pulse.

10. The circuit of the claim 9, wherein the first impedance value is lower than the second impedance value.

11. (canceled)

12. The circuit of claim 9, wherein the driver control circuit is configured to perform an XOR operation on pulses of an input signal corresponding to the pulse and the immediately preceding pulse of the output signal in order to generate the control signal.

13. The circuit of claim 12, wherein the control circuit is further configured to:
receive a clock signal oscillating at a rate that is twice a rate of the output signal; and
perform the XOR operation once per clock cycle of the clock signal.

14. A circuit comprising:
a comparison circuit configured to:
compare logic levels of consecutive pulses of a plurality of pulses of a signal;
output a control signal to activate a secondary circuit of an output driver circuit in response to the comparison indicating that the logic levels are different; and
output the control signal to deactivate the secondary circuit in response to the comparison indicating that the logic levels are the same; and
an input circuit comprising:
a first tracking circuit configured to track the signal on one of rising edges or falling edges of a clock signal to generate a first tracked signal; and
a second tracking circuit configured to track the first tracked signal on the other of the rising edges or the falling edges of the clock signal; and
a logic circuit configured between the first tracking circuit and the second tracking circuit, the logic circuit configured to pass the first tracked signal to the second tracking circuit in response to an enable signal indicating that the output driver circuit is to generate an output signal based on the signal.

15. The circuit of claim 14, wherein the comparison circuit comprises:
an XOR logic circuit configured to:
perform an XOR operation on the logic levels; and
generate an XOR output signal based on the XOR operation; and
a tracking circuit configured to track the XOR output signal on edges of a clock signal in order to generate the control signal.

16. The circuit of claim 15, wherein the XOR logic circuit is further configured to:
receive the first tracked signal and the second tracked signal; and
perform the XOR operation using the first tracked signal and the second tracked signal.

17. The circuit of claim 16, wherein the first tracking circuit is configured to track the signal on the falling edges, the second tracking circuit is configured to track the first tracked signal on the rising edges, and the tracking circuit of the comparison circuit is configured to track the XOR output signal on the rising edges.

18. The circuit of claim 16, wherein the input circuit is further configured to receive a clock signal, wherein a rate of the clock signal is twice a rate of the signal.

19. (canceled)

20. The circuit of claim 16, further comprising:
an output circuit configured to output an intermediate signal to a multiplexer circuit,
wherein the second tracking circuit of the input circuit is configured to output to the second tracked signal to both the output circuit for generation of the intermediate signal and to the XOR logic circuit for generation of the control signal.

21. (canceled)
